(19) United States
(12) Patent Application Publication
(10) Pub. No.: US 2025/0218938 A1
(43) Pub. Date: Jul. 3, 2025

(54) DEVICE HAVING MD CONTACT COUPLED TO ACTIVE REGION AND BV STRUCTURE, AND METHOD OF MANUFACTURING SAME

(71) Applicant: TAIWAN SEMICONDUCTOR MANUFACTURING COMPANY, LTD., Hsinchu (TW)

(72) Inventors: Wei-Cheng KANG, Hsinchu (TW); Sheng-Feng HUANG, Hsinchu (TW); Shang-Wei FANG, Hsinchu (TW); Meng-Hung SHEN, Hsinchu (TW); Jiann-Tyng TZENG, Hsinchu (TW)

(21) Appl. No.: 18/649,087

(22) Filed: Apr. 29, 2024

Related U.S. Application Data
(60) Provisional application No. 63/617,198, filed on Jan. 3, 2024.

(51) Int. Cl. H01L 23/528; H01L 21/8234; H01L 27/088; H01L 29/417

(52) U.S. Cl. CPC H01L 23/528; H10D 64/254; H10D 84/0149; H10D 84/038; H10D 84/83

(57) ABSTRACT

A device including: a first active region; first and second ohmic-contact layers correspondingly on, and coupled to, a front side and a back side of a first portion of the first active region; a metal-to-source/drain (MD) contact including a first part on the first ohmic-contact layer and at least a second part or a third part correspondingly aside a first lateral side or a second lateral side of the first portion of the first active region, the first part of the MD contact being coupled to the first ohmic-contact layer; and a buried-via (BV) structure including: a first part under, and coupled to, the second ohmic-contact layer; and a second part under, and coupled to, the MD contact.

### PRIORITY CLAIM

This application claims the priority of U.S. Provisional Application No. 63/617,198, filed Jan. 3, 2024, which is incorporated herein by reference in its entirety.

### BACKGROUND

The semiconductor integrated circuit (IC) industry produces a wide variety of analog and digital devices to address issues in a number of different areas. Developments in semiconductor process technology nodes have progressively reduced component sizes and tightened spacing resulting in progressively increased transistor density. ICs have become smaller.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIGS. 1A-1F are corresponding cross-sectional views, in accordance with some embodiments.

FIGS. 2A-2B are corresponding layout diagrams, in accordance with some embodiments.

FIG. 3A is a schematic diagram, in accordance with some embodiments.

FIGS. 3B-3D are corresponding layout diagrams, in accordance with some embodiments.

FIGS. 4A-4C are corresponding cross-sectional views, in accordance with some embodiments.

FIGS. 5A-5B are corresponding layout diagrams, in accordance with some embodiments.

FIG. 5C is a combination schematic and three-quarter perspective diagram, in accordance with some embodiments.

FIGS. 6A-6D are corresponding cross-sectional views, in accordance with some embodiments.

FIGS. 7A-7D are flowcharts of corresponding methods of manufacturing a memory device, in accordance with some embodiments.

FIG. 8 is a block diagram of an electronic design automation (EDA) system in accordance with some embodiments.

FIG. 9 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, are used herein for case of description to describe one element or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

In some embodiments, a device includes a metal-to-source/drain (MD) contact coupled to an active region and a buried-via (BV) structure. In some embodiments, the MD contact wraps is coupled to the active region and wraps around the active region to also be coupled to the BV structure, where such an MD contact sometimes is referred to as a wrap-around (WA) MD contact (WA_MD contact). In some embodiments, more particularly, a device includes: a first active region; first and second ohmic-contact layers correspondingly on, and coupled to, a front side and a back side of a first portion of the first active region; an MD contact including a first part on the first ohmic-contact layer and at least a second part or a third part correspondingly aside a first lateral side or a second lateral side of the first portion of the first active region, the first part of the MD contact being coupled to the first ohmic-contact layer; and a BV structure including a first part under, and coupled to, the second ohmic-contact layer and a second part under, and coupled to, the MD contact.

According to another approach, a counterpart device includes: an MD contact which is a counterpart to the WA_MD; a counterpart active region; and a counterpart BV structure. Relative to a short axis of the counterpart active region, the counterpart BV structure according to the other approach does not extend significantly beyond the counterpart active region. As such, the counterpart device according to the other approach has only one current-path between the other approach's counterpart active region and counterpart BV structure. By contrast, a device including a WA_MD contact (WA_MD-based device) according to some embodiments has at least two current paths between the active region and the BV structure due to the WA_MD wrapping around the active region and thereby also being coupled to the BV structure. A WA_MD-based device experiences substantially lower resistance between the BV structure and the active region, R_WA_MD, as compared to a counterpart resistance, R_OA, according to the other approach. As such, a WA_MD-based device according to some embodiments experiences reduced energy consumption, e.g., due to reduced resistive losses, or the like, as compared to the other approach. In some embodiments, R_WA_MD≤(≈0.5)*R_OA.

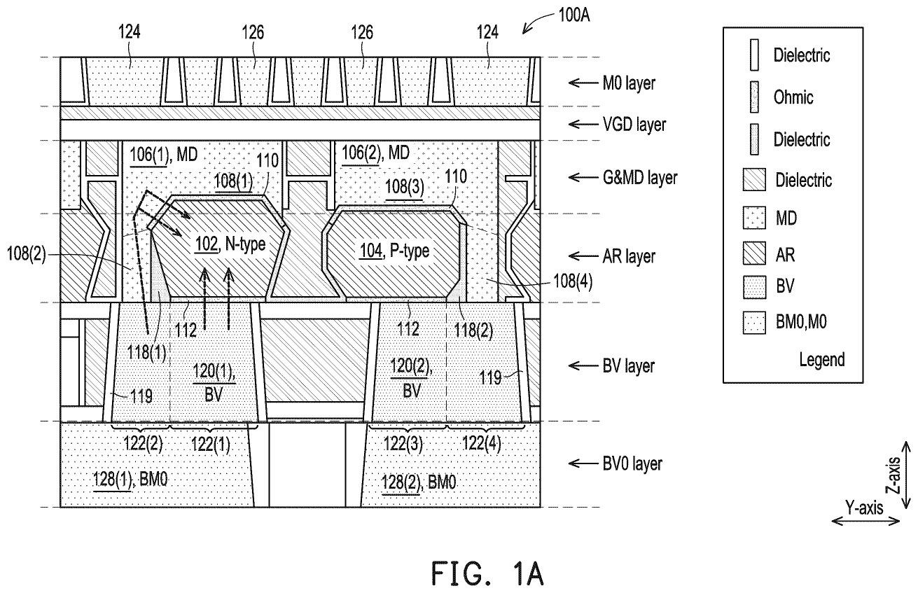

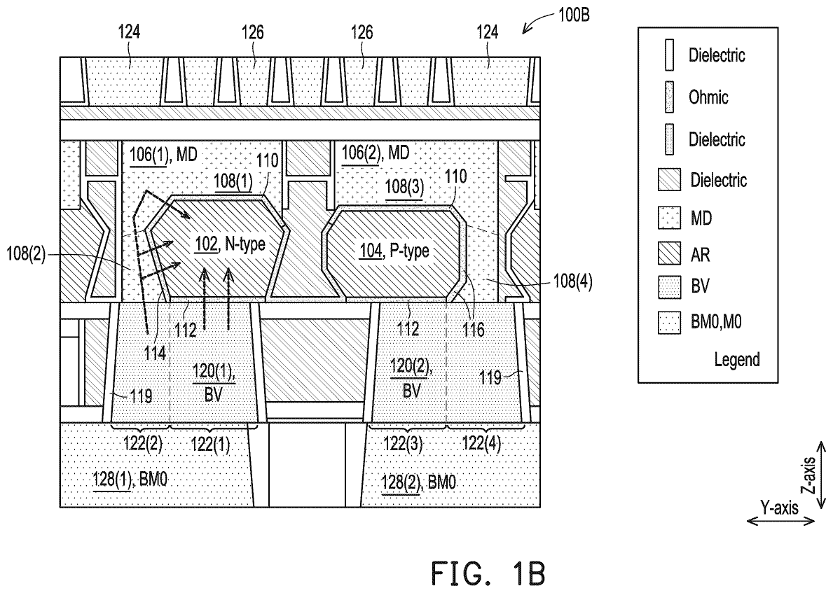

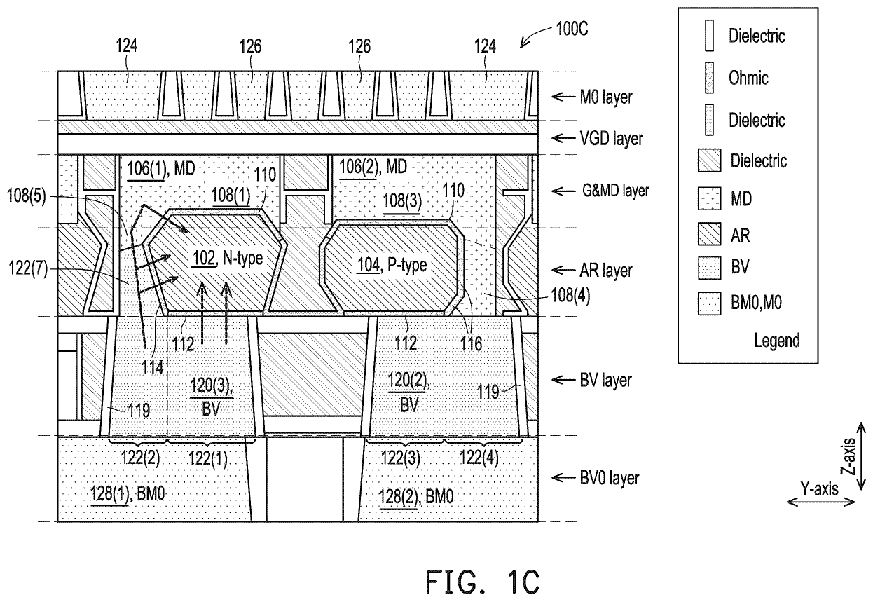

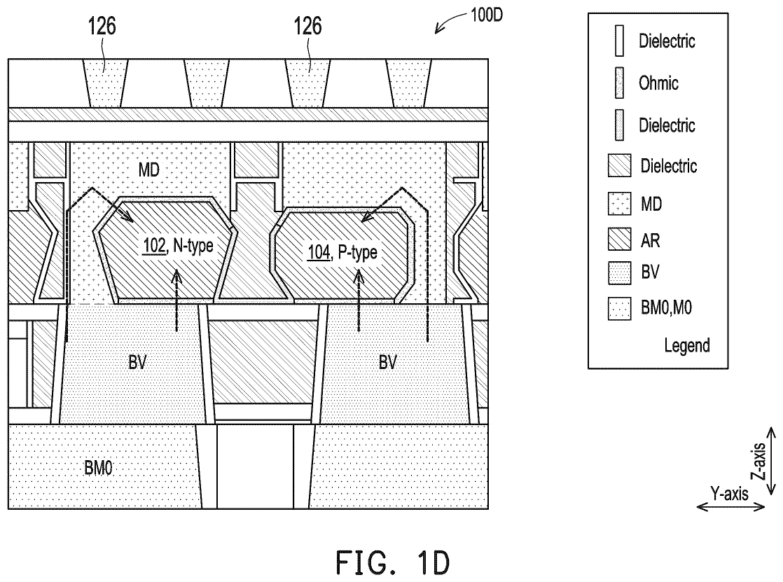

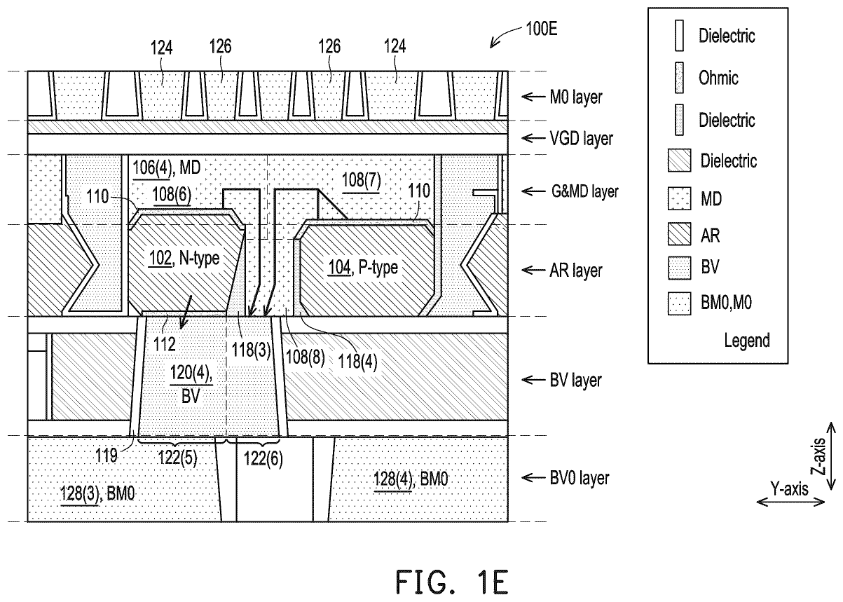

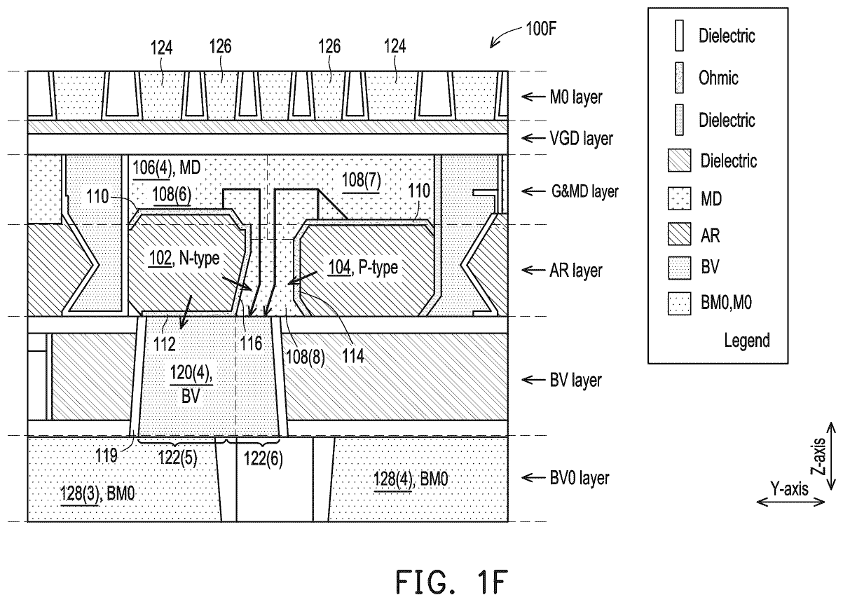

FIG. 1A is a cross-sectional view of a device 100A, in accordance with some embodiments.

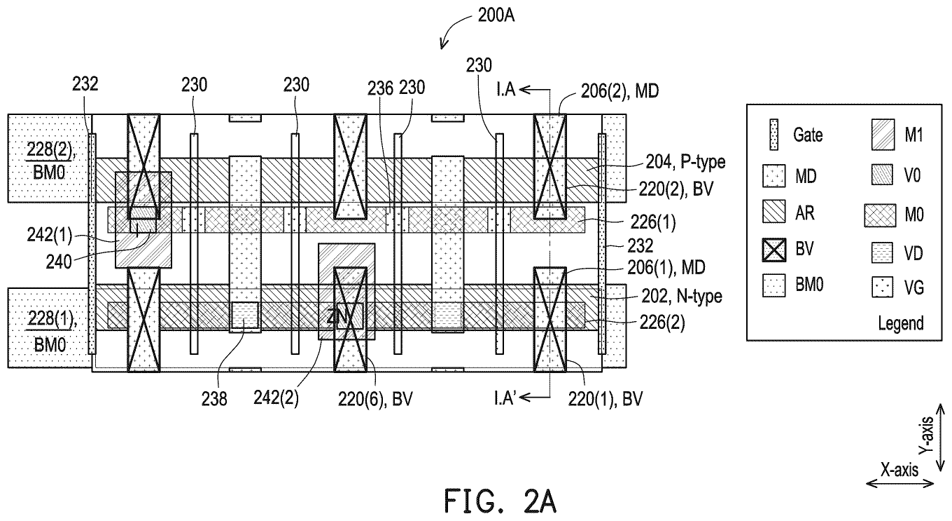

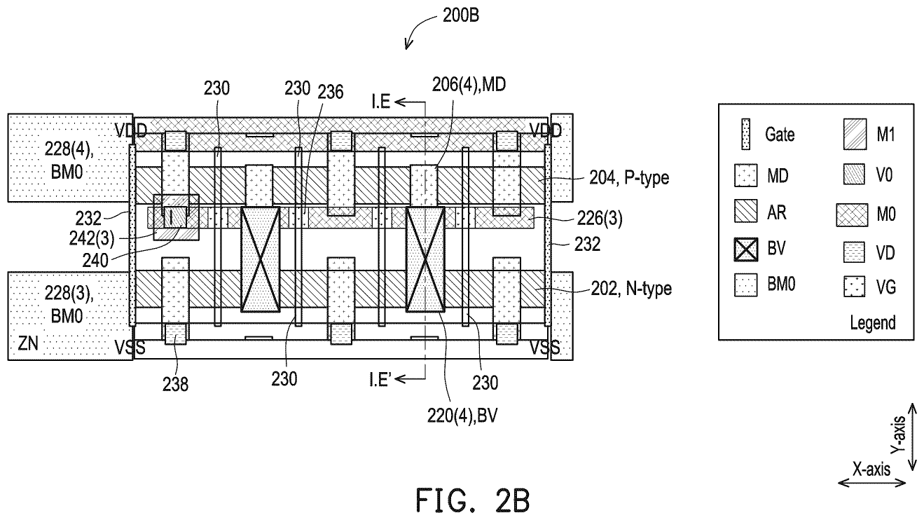

Device 100A is an example of a device having an MD contact coupled to an active region and a BV structure, as discussed below. Device 100A is an example of a device having a WA_MD contact. In some embodiments, device 100A is an example of a device that corresponds to section line I.A-I.A′ of FIG. 2A.

FIG. 1A is arranged according to an orthogonal Cartesian coordinate system in which first, second and third directions are, e.g., correspondingly parallel to the X-axis, the Y-axis and the Z-axis. In some embodiments, the first, second and third orthogonal directions are something other than being correspondingly parallel to the X-axis, the Y-axis and the Z-axis.

Device 100A is organized into layers relative to the Z-axis. The layers of device 100A include: an active region (AR) layer; G&MD layer on the AR layer; a VGD layer on the G&MD layer; a first layer of metallization layer on the VGD layer; a BV layer under the AR layer; and a first buried layer of metallization under the VGD layer. It is noted that the layer boundaries indicated in FIG. 1A are approximate, especially in regard to the boundary between the G&MD layer and the AR layer.

The AR layer includes active regions that include source/drain (S/D) regions and channel regions between corresponding S/D regions. In some embodiments, the formation of active regions includes: forming a semiconductor layer (e.g., a silicon layer) on a substrate by, e.g., epitaxy resulting in an epitaxial layer; in general, doping selected regions of the semiconductor layer that will become active regions correspondingly with positive-type (P-type) or negative-type (N-type) dopants, e.g., by ion implantation; in first portions of the selected regions that will become S/D regions, relatively more heavily doping the first portions; and in the remaining regions of the semiconductor layer, i.e., in the non-selected regions of the semiconductor layer, converting the remaining regions into insulating regions, e.g., forming shallow trench isolation (STI) regions. In a context of field-effect transistors (FETs): a P-type dopant is used for positive-channel metal-oxide semiconductor (PMOS) transistor technologies, e.g., P-type FETs (PFETs); and an N-type dopant is used for negative-channel metal-oxide semiconductor (NMOS) transistor technologies, e.g., N-type FETs (NFETs). In a context of complementary metal-oxide semiconductor (CMOS) transistor technology, the AR layer includes both P-type active regions and N-type active regions. In some embodiments, the formation of active regions further includes, in second portions of the selected regions that will become channel regions, relatively more lightly doping the second portions.

In FIG. 1A, the G&MD layer includes MD contacts (discussed below) and/or gate lines/structures (discussed below), where G&MD is an acronym for gate-and-MD-contacts, and MD is an acronym discussed below. In some embodiments, parts of the MD contacts extend at least substantially into the AR layer, as discussed below. The VGD layer includes VG structures (discussed below) or VD structures (discussed below).

The first layer of metallization layer includes segments. In some embodiments, depending upon the numbering convention of the corresponding process node by which such a device is fabricated, the first layer of metallization is either metallization layer zero (MET0) or metallization layer one (MET1), and correspondingly a first layer of interconnection on the first layer if metallization is either interconnection layer zero (VIA0) or interconnection layer one (VIA1). In FIG. 1A, and in the other figures disclosed herein, the following nomenclature is adopted: the first layer of metallization is assumed to be MET0; the first layer of interconnection is assumed to be VIA0; the second layer of metallization is assumed to be MET1, the second layer of interconnection is assumed to be VIA1; and the third layer of metallization is assumed to MET2. Metallization segments in layer MET0 are referred to as M0 segments. Via structures in layer VIA0 are referred to as V0 structures. Metallization segments in layer MET1 are referred to as M1 segments. Via structures in layer VIA1 are referred to as V1 structures. Metallization segments in layer MET2 are referred to as M2 segments.

The BV layer includes buried via (BV) structures (discussed below). As discussed below, in some embodiments, parts of the BV structures extend at least substantially into the AR layer. The first buried layer of metallization includes metallization segments. Expanding the nomenclature discussed above, the first buried layer of metallization is referred to as BM0, and metallization segments included in layer BM0 are referred to as BM0 segments.

In FIG. 1A, device 100A includes: an instance of an AR 102 configured with a first dopant type; an instance of an AR 104 configured with a second dopant type; instances of ohmic contact (OC) layers 110 and 112; instances of dielectric structures and layers including dielectric structures 118(1) and 118(2) and 119; MD contacts 106(1) and 106(2); BV structures 120(1) and 120(2); instances of M0 segments 124; instances of M0 segments 126; and BM0 segments 128(1) and 128(2). In some embodiments, MD is an acronym for metal-to-S/D or metal-on-S/D or metal-over-S/D. In some embodiments, MD is an acronym for metal-on-diffusion or metal-over-diffusion. MD contact 106(1) includes a first part 108(1) and a second part 108(2). MD contact 106(2) includes a first part 108(3) and a second part 108(4). BV structure 120(1) includes a first part 122(1) and a second part 122(2). BV structure 120(2) includes a first part 122(3) and a second part 122(4).

FIG. 1A assumes that the first dopant is N-type and the second dopant is P-type such that AR 102 is an N-type AR and AR 104 is a P-type AR. For simplicity of illustration, not all elements of device 100A are called out with reference numbers. In some embodiments, one or more instances of each of OC layers 110 and 112 include a corresponding silicide layer, or the like.

In FIG. 1A, relative to the Y-axis, the width of the instances of M0 segment 124 is substantially greater than the width of instances of M0 segment 126. In some embodiments, the width of the instances of M0 segment 124 is approximately the same as the width of instances of M0 segment 126. The pitch of instances of M0 segment 124 is greater than the pitch of instances of M0 segment 126. In some embodiments, instances of M0 segment 124 are omitted (see FIG. 1D). In some embodiments, the instances of M0 segment 124 are power grid (PG) segments configured for corresponding reference voltages, e.g., VDD, VSS, or the like. In some embodiments, instances of M0 segment 126 are configured for routing signals. Examples of routing signals include input/output (I/O) signals, data signals, control signals, or the like.

A first instance of OC layer 110 is on AR 102. First part 108(1) of MD contact 106(1) is on the first instance of OC layer 110. The first instance of OC layer 110 facilitates an electrical coupling between first part 108(1) of MD contact 106(1) and AR 102. A second instance of OC layer 110 is on AR 104. First part 108(3) of MD contact 106(2) is on the second instance of OC layer 110. The second instance of OC layer 110 facilitates an electrical coupling between first part 108(3) of MD contact 106(2) and AR 104.

A first instance of OC layer 112 is under AR 102. First part 122(1) of BV structure 120(1) is under the first instance of OC layer 112. The first instance of OC layer 112 facilitates an electrical coupling between first part 122(1) of BV structure 120(1) and AR 102. A second instance of OC layer 112 is under AR 104. First part 122(3) of BV structure 120(2) is under the second instance of OC layer 112. The second instance of OC layer 112 facilitates an electrical coupling between first part 122(3) of BV structure 120(2) and AR 104.

In FIG. 1A, dielectric structure 118(1) is on/against a first lateral side of AR 102. Relative to the Y-axis, a second lateral side of AR 102 is proximal to AR 104 whereas the first side of AR 102 is distal to AR 104. Dielectric structure 118(2) is on/against a second lateral side of AR 104. Relative to the Y-axis, a first lateral side of AR 104 is proximal to AR 102 whereas the second side of AR 104 is distal to AR 102. In some embodiments, a lateral side of either AR 102 or AR 104 is referred to as a flank. In FIG. 1A, relative to the Y-axis, the first lateral side of each of ARs 102 and 104 is the left side and the second lateral side of each of ARs 102 and 104 is the right side.

Dielectric structure 118(1) separates second part 108(2) of MD contact 106(1) from the left side of AR 102. A bottom surface of dielectric structure 118(1) is on a first portion of second part 122(2) of BV structure 120(1). Dielectric structure 118(2) separates second part 108(4) of MD contact 106(2) from the right side of AR 104. A bottom surface of dielectric structure 118(2) is on a first portion of second part 122(3) of BV structure 120(2).

Regarding MD contact 106(1), an imaginary boundary between second part 108(2) and first part 108(1) is indicated by a phantom (dashed) line. Relative to the Z-axis, second part 108(2) of MD contact 106(1) extends alongside the left side of AR 102. Relative to the Z-axis, second part 108(2) of MD contact 106(1) extends substantially into the AR layer. A lower end of second part 108(2) of MD contact 106(1) is on a second portion of second part 122(2) of BV structure 120(1). As such, second part 108(2) of MD contact 106(1) is electrically coupled to second part 122(2) of BV structure 120(1).

Regarding FIG. 1A, in some embodiments, a lower surface at the back side of AR 102 is substantially planar and substantially parallel to the X-Y plane. An upper surface of first part 122(1) of BV structure 120(1) is substantially planar and substantially parallel to the lower surface of AR 102. An upper surface of second part 122(2) of BV structure 120(1) is substantially planar and substantially parallel to the X-Y plane. The upper surface of second part 122(2) of BV structure 120(1) further is substantially coplanar with the upper surface of first part 122(1) of BV structure 120(1). A lower surface of the lower end of second part 108(2) of MD contact 106(1) is substantially planar and substantially parallel to the upper surface of second part 122(2) of BV structure 120(1), which facilitates an electrical coupling between the lower end of second part 108(2) of MD contact and second part 122(2) of BV structure 120(1).

Regarding MD contact 106(2), an imaginary boundary between second part 108(4) and first part 108(3) is indicated by a phantom (dashed) line. Relative to the Z-axis, second part 108(4) of MD contact 106(2) extends alongside the right of AR 104. Relative to the Z-axis, second part 108(4) of MD contact 106(2) extends substantially into the AR layer. A lower end of second part 108(4) of MD contact 106(2) is on a second portion of second part 122(4) of BV structure 120(2). As such, second part 108(4) of MD contact 106(2) is electrically coupled to second part 122(4) of BV structure 120(2).

BV structure 120(1) is on BM0 segment 128(1). BV structure 120(2) is on BM0 segment 128(2). In some embodiments, BM0 segment 128(1) or 128(2) is configured for a corresponding reference voltage, e.g., VDD, VSS, or the like.

In FIG. 1A, a first current-path between BV structure 120(1) and AR 102 is from first part 122(1) of BV structure 120(1) through the first instance of OC layer 112 into AR 102. Second part 108(2) of MD contact 106(1) facilitates a second current-path between BV structure 120(1) and AR 102. The second current-path between BV structure 120(1) and AR 102 is from second part 122(2) of BV structure 120(1) through second part 108(2) of MD contact 106(1) and a section of the first instance of OC layer 110 into AR 102.

A resistance of the first current-path, R_bs, is represented by a resistance across the first instance of ohmic contact layer 112, R_OC112, such that R_bs≈R_OC112, where bs is an acronym for back side. A resistance of the second current-path, R_fs, is represented by a combination including: a resistance of an ohmic boundary between second part 122(2) of BV structure 120(1) and second part 108(2) of MD contact 106(1), R_MDBV; a resistance of second part 108(2) of MD contact 106(1), R_MD; and a resistance across the section of the first instance of ohmic contact layer 110, R_OC110. As such, R_fs≈R_MDBV+R_MD+R_OC110, where fs is an acronym for front side.

The first and second current-paths between BV structure 120(1) and AR 102 are in parallel which reduces a total resistance between BV structure 120(1) and AR 102 of device 100A, R_BVAR102A. In general, two resistors in parallel, R1 and R2, have an equivalent total resistance, R_tot, as follows: R_tot=(R1*R2)/(R1+R2). A total resistance between BV structure 120(1) and AR 102 of device 100A is represented as R_BVAR102A=(R_bs*R_fs)/(R_bs+R_fs). In some embodiments, as an example, R_MDBV≈0.2*R_bs, R_MD≈0.2*R_bs and R_OC110≈0.5*R_bs such that R_fs≈(0.2+0.2+0.5)*R_bs≈0.9*R_bs and R_BVAR102A≈0.5*R_bs.

In FIG. 1A, a first current-path between BV structure 120(2) and AR 104 is from first part 122(3) of BV structure 120(2) through the second instance of OC layer 112 into AR 104. Second part 108(4) of MD contact 106(2) facilitates a second current-path between BV structure 120(2) and AR 104. The second current-path between BV structure 120(2) and AR 104 is from second part 122(4) of BV structure 120(2) through second part 108(4) of MD contact 106(2) and a section of the second instance of OC layer 110 into AR 104. The representation of a total resistance between BV structure 120(2) and AR 104 of device 100A, R_BVAR104A, is similar to the representation of R_BVAR102A such that R_BVAR104A≈0.5*R_bs.

According to another approach, a device counterpart to device 100A includes an MD contact which is a counterpart to MD contact 106(1), an active region which is a counterpart to AR 102 and a BV structure which is a counterpart to first part 122(1) of BV structure 120(1). Relative to the Y-axis, the BV structure according to the other approach does not extend significantly beyond the active region according to the other approach. As such, the device counterpart according to the other approach has only one current-path between the other approach's counterparts to AR 102 and BV structure 120(1) of device 100A such that a total resistance between the other approach's counterparts to AR 102 and first part 122(1) of BV structure 120(1) is represented as R_bs, which causes the other approach to experience higher energy consumption, e.g., due to greater resistive losses, or the like. By contrast, device 100A (or other such embodiments as disclosed herein) has a substantially lower resistance between BV structure 120(1) and AR 102, namely R_BVAR102A≈0.5*R_bs, and between BV structure 120(2) and AR 104, namely R_BVAR104A≈0.5*R_bs, such that device 100A (or the like) experiences reduced energy consumption, e.g., due to reduced resistive losses, or the like, as compared to the other approach.

FIG. 1B is a cross-sectional view of a device 100B, in accordance with some embodiments.

Device 100B is an example of a device having an MD contact coupled to an active region and a BV structure. Device 100B is an example of a device having a WA_MD contact. Device 100B of FIG. 1B is similar to device 100A of FIG. 1A. For brevity, the discussion will focus on differences of device 100B as compared to device 100A rather than on similarities. In some embodiments, device 100B is an example of a device that corresponds to section line I.A-I.A′ of FIG. 2A.

As compared to device 100A of FIG. 1A, device 100B of FIG. 1B further includes a first instance of OC layer 114 and a first instance of OC layer 116. In device 100B, the first instance of OC layer 114 and the first instance of OC layer 116 correspondingly replace dielectric structures 118(1) and 118(2) of device 100A. OC layer 114 is on/against the left side of AR 102. OC layer 116 is on/against the right second lateral side of AR 104. In some embodiments, one or more instances of each of OC layers 114 and 116 include a corresponding silicide layer, or the like.

In FIG. 1B, the first instance of OC layer 114 facilitates a third current-path between BV structure 120(1) and AR 102. The third current-path between BV structure 120(1) and AR 102 is from second part 122(2) of BV structure 120(1) through second part 108(2) of MD contact 106(1) and the first instance of OC layer 114 into AR 102. The second and third current-paths between BV structure 120(1) and AR 102 differ in that the former includes the first instance of OC layer 110 whereas the latter includes the first instance of OC layer 114.

The first instance of OC layer 116 facilitates a third current-path between BV structure 120(2) and AR 104. The third current-path between BV structure 120(2) and AR 104 is from second part 122(4) of BV structure 120(2) through second part 108(4) of MD contact 106(2) and the first instance of OC layer 116 into AR 104. The second and third current-paths between BV structure 120(2) and AR 104 differ in that the former includes the second instance of OC layer 110 whereas the latter includes the first instance of OC layer 116.

A resistance of the third current-path, R_ls, is represented by a combination including: R_MDBV; R_MD; and a resistance across the first instance of OC layer 114, R_OC114. As such, R_ls≈R_MDBV+R_MD+R_OC114, where ls is an acronym for lateral side.

The second and third current-paths between BV structure 120(1) and AR 102 are effectively in parallel with each other, and each is in parallel with the first current-path between BV structure 120(1) and AR 102, which reduces a total resistance between BV structure 120(1) and AR 102 of device 100B, R_BVAR102B. A total resistance between BV structure 120(1) and AR 102 of device 100B is represented as R_BVAR102B=(R_bs*R_fs*R_ls)/(R_bs+R_fs+R_ls).

Relative to a long axis of each, typically, the length of the first instance of OC layer 116 is greater than a length of the section of the first instance of ohmic contact layer 110 represented by R_OC110. In some embodiments, relative to a short axis of each, typically, the thickness of the first instance of OC layer 116 is approximately equal to the thickness of the section of the first instance of ohmic contact layer 110 represented by R_OC110. As such, in some embodiments, R_OC114≤R_OC110. Extending the example of FIG. 1A, and further assuming for example that R_OC114≈R_OC110 such that R_OC114≈0.5*R_bs, then R_BVAR102D≈0.3*R_bs.

Device 100B (or other such embodiments as disclosed herein) has a substantially lower resistance between BV structure 120(1) and AR 102, namely R_BVAR102B=0.3*R_bs, and between BV structure 120(2) and AR 104, namely R_BVAR104B≈0.3*R_bs, such that device 100B (or the like) experiences reduced energy consumption, e.g., due to reduced resistive losses, or the like, as compared to the other approach.

FIG. 1C is a cross-sectional view of a device 100C, in accordance with some embodiments.

Device 100C is an example of a device having an MD contact coupled to an active region and a BV structure. Device 100C is an example of a device having a WA_MD contact. Device 100C of FIG. 1C is similar to device 100B of FIG. 1B. For brevity, the discussion will focus on differences of device 100C as compared to device 100B rather than on similarities. In some embodiments, device 100C is an example of a device that corresponds to section line I.A-I.A′ of FIG. 2A.

As compared to device 100B of FIG. 1B, device 100C of FIG. 1C further includes a third part 122(7) of BV structure 120(1) resulting in an enlarged version of BV structure 120(1). The enlarged version of BV structure 120(1) in FIG. 1C is assigned reference number 120(3) in FIG. 1C. In device 100C, in terms of occupied space, third part 122(7) of BV structure 120(3) effectively replaces much of second part 108(2) of MD contact 106(1) of FIG. 1B, resulting in a truncated version of MD contact 106(1) that includes a truncated version of first part 108(1) thereof. The version of first part 108(1) and the truncated version of MD contact 106(1) in FIG. 1C are correspondingly assigned reference numbers 108(5) and 106(3) in FIG. 1C.

Third part 122(7) of BV structure 120(3) is under and coupled to first part 108(5) of MD contact 106(3). Relative to the Z-axis, third part 122(7) of BV structure 120(3) extends alongside the left side of AR 102. Third part 122(7) of BV structure 120(3) is on/against OC layer 114. As such, third part 122(7) of BV structure 120(3) is electrically coupled to first part 108(5) of MD contact 106(3) and to AR 102, the latter being through the first instance of OC layer 114. In some embodiments, a boundary between third part 122(7) of BV structure 120(3) and first part 108(5) of MD contact 106(3) approximates the imaginary boundary between second part 108(2) and first part 108(1) of MD contact 106(1) in FIG. 1B.

In some embodiments, upper and lower surfaces correspondingly at the front and back sides of AR 102 are substantially planar and substantially parallel to the X-Y plane. Relative to the Z-axis: third part 122(7) of BV structure 120(3) extends substantially above the lower surface of AR 102; third part 122(7) of BV structure 120(3) extends substantially into the AR layer; the portion of first part 108(5) of MD contact 106(3) which abuts an upper end of BV structure 120(3) extends significantly below an uppermost surface of MD contact 106(1); and first part 108(5) of MD contact 106(3) extends significantly into the AR layer.

Like second part 108(2) of MD contact 106(1) in FIG. 1B, third part 122(7) of BV structure 120(3) in FIG. 1C facilitates a third current-path between BV structure 120(3) and AR 102. The third current-path between BV structure 120(3) and AR 102 is from second part 122(2) of BV structure 120(3) through third part 122(7) of BV structure 120(3) and the first instance of OC layer 114 into AR 102. The third current-paths between BV structure 120(3) and AR 102 in device 100C of FIG. 1C and device 100B in FIG. 1B differ in that the former includes third part 122(7) of BV structure 120(3) whereas the latter includes second part 108(2) of MD contact 106(1).

In some embodiments, a resistance of third part 122(7) of BV structure 120(3) in FIG. 1C, R_BV, is approximately equal to the resistance of second part 108(2) of MD contact 106(1) in FIG. 1B, R_MD, such that R_BV≈R_MD. In such embodiments, a total resistance between BV structure 120(3) and AR 102 of device 100C, R_BVAR102C, is approximately equal to the total resistance between BV structure 120(3) and AR device 102 of 100B, R_BVAR102B, such that R_BVAR102C=R_BVAR102B≈0.3*R_bs.

Device 100C (or other such embodiments as disclosed herein) has a substantially lower resistance between BV structure 120(3) and AR 102, namely R_BVAR102C≈0.3*R_bs, and between BV structure 120(2) and AR 104, namely R_BVAR104B≈0.5*R_bs, such that device 100C (or the like) experiences reduced energy consumption, e.g., due to reduced resistive losses, or the like, as compared to the other approach.

FIG. 1D is a cross-sectional view of a device 100D, in accordance with some embodiments.

Device 100D is an example of a device having an MD contact coupled to an active region and a BV structure. Device 100D is an example of a device having a WA_MD contact. Device 100D of FIG. 1D is similar to device 100A of FIG. 1A. For brevity, the discussion will focus on differences of device 100D as compared to device 100A rather than on similarities. In some embodiments, device 100D is an example of a device that corresponds to section line I.A-I.A′ of FIG. 2A.

In FIG. 1D, instances of M0 segment 124 of FIG. 1A are omitted. Furthermore, the width of instances of M0 segment 126 in FIG. 1D is greater than the width of instances of M0 segment 126 in FIG. 1A. The pitch of instances of M0 segment 126 in FIG. 1D is greater than the pitch of instances of M0 segment 126 in FIG. 1A. In some embodiments, the increased M0 pitch experienced by device 100D is equal to greater than about a 20% improvement as compared to another approach.

FIG. 1E is a cross-sectional view of a device 100E, in accordance with some embodiments.

Device 100E is an example of a device having an MD contact coupled to an active region and a BV structure. Device 100E is an example of a device having a WA_MD contact. Device 100E of FIG. 1E is similar to device 100A of FIG. 1A. For brevity, the discussion will focus on differences of device 100E as compared to device 100A rather than on similarities. In some embodiments, device 100E is an example of a device that corresponds to section line I.E-I.E′ of FIG. 2B.

As compared to device 100A of FIG. 1A, device 100E of FIG. 1E further includes: instances of dielectric structures and layers including dielectric structures 118(3) and 118(4); MD contact 106(4); BV structure 120(4); and BM0 segments 128(3) and 128(4). Device 100E does not include MD contacts 106(1) and 106(2), BV structures 120(1)-120(2), nor BM0 segments 128(1)-128(2) of device 100A.

MD contact 106(4) includes a first part 108(6), a second part 108(7) and a third part 108(8). Dielectric structure 118(3) is on/against a right side of AR 102. Dielectric structure 118(4) is on/against a left side of AR 104. BV structure 120(4) includes a first part 122(4) and a second part 122(5).

Dielectric structure 118(3) separates third part 108(8) of MD contact 106(4) from the right side of AR 102. A bottom surface of dielectric structure 118(3) is on a first portion of second part 122(5) of BV structure 120(4). Dielectric structure 118(4) separates third part 108(8) of MD contact 106(4) from the left side of AR 104.

Regarding MD contact 106(4): a first imaginary boundary between (A) third part 108(8) and (B) first part 108(6) and second part 108(7) is indicated by a phantom (dashed) line that is substantially parallel the X-axis; a second imaginary boundary between first part 108(6) and second part 108(7) is indicated by a phantom (dashed) line that is substantially parallel the Z-axis.

Relative to the Z-axis, third part 108(8) of MD contact 106(4) extends alongside the right side of AR 102 and the left side of AR 104. Relative to the Z-axis, third part 108(8) of MD contact 106(4) extends substantially into the AR layer. A lower end of third part 108(8) of MD contact 106(4) is on a second portion of second part 122(5) of BV structure 120(4). As such, third part 108(8) of MD contact 106(4) is electrically coupled to second part 122(5) of BV structure 120(4).

In some embodiments, a lower surface at the back side of AR 102 is substantially planar and substantially parallel to the X-Y plane. An upper surface of first part 122(4) of BV structure 120(4) is substantially planar and substantially parallel to the lower surface of AR 102. An upper surface of second part 122(5) of BV structure 120(4) is substantially planar and substantially parallel to the X-Y plane. The upper surface of second part 122(5) of BV structure 120(4) further is substantially coplanar with the upper surface of first part 122(4) of BV structure 120(4). A lower surface of the lower end of third part 108(8) of MD contact 106(4) is substantially planar and substantially parallel to the upper surface of second part 122(5) of BV structure 120(4), which facilitates an electrical coupling between the lower end of third part 108(8) of MD contact and second part 122(5) of BV structure 120(4).

A majority of first part 122(4) of BV structure 120(4) is on BM0 segment 128(3). In some embodiments, BM0 segment 128(3) or 128(2) is configured for a corresponding reference voltage, e.g., VDD, VSS, or the like.

In FIG. 1E, third part 108(8) of MD contact 106(4) facilitates a second current-path between BV structure 120(4) and AR 102 and a first current-path between BV structure 120(4) and AR 104. A first current-path between BV structure 120(4) and AR 102 is from first part 122(4) of BV structure 120(4) through the first instance of OC layer 112 into AR 102. The second current-path between BV structure 120(4) and AR 102 is from second part 122(5) of BV structure 120(4) through third part 108(8) of MD contact 106(4) and a section of the first instance of OC layer 110 into AR 102. The first current-path between BV structure 120(4) and AR 104 is from first part 122(4) of BV structure 120(4) through the second instance of OC layer 112 into AR 104.

According to another approach, a device counterpart to device 100E includes an MD contact which is a counterpart to MD contact 106(4), an active region which is a counterpart to AR 102 and a BV structure which is a counterpart to first part 122(4) of BV structure 120(4). Relative to the Y-axis, the BV structure according to the other approach does not extend significantly beyond the active region according to the other approach. The device counterpart according to the other approach has only one current-path between the other approach's counterparts to AR 102 and first part 122(4) of BV structure 120(4) of device 100E such that a total resistance between the other approach's counterparts to AR 102 and BV structure 120(4) is represented as R_bs, which causes the other approach to experience higher energy consumption, e.g., due to greater resistive losses, or the like. By contrast, device 100E (or other such embodiments as disclosed herein) has a substantially lower resistance due to the first and second current-paths between BV structure 120(4) and AR 102 and the first current-path between BV structure 120(4) and AR 104, such that device 100E (or the like) experiences reduced energy consumption, e.g., due to reduced resistive losses, or the like, as compared to the other approach.

FIG. 1F is a cross-sectional view of a device 100F, in accordance with some embodiments.

Device 100F is an example of a device having an MD contact coupled to an active region and a BV structure. Device 100F is an example of a device having a WA_MD contact. Device 100F of FIG. 1F is similar to device 100E of FIG. 1E. For brevity, the discussion will focus on differences of device 100F as compared to device 100E rather than on similarities. In some embodiments, device 100F is an example of a device that corresponds to section line I.E-I.E′ of FIG. 2B.

As compared to device 100E of FIG. 1E, device 100F of FIG. 1F further includes an instance of OC layer 114 and an instance of OC layer 116. In device 100F, the instance of OC layer 114 and the instance of OC layer 116 correspondingly replace dielectric structures 118(3) and 118(4) of device 100E. The instance of OC layer 114 is on/against the left side of AR 104 in FIG. 1F. The instance of OC layer 116 is on/against the right side of AR 102.

In FIG. 1F, the instance of OC layer 116 facilitates a third current-path between BV structure 120(4) and AR 102. The current-path between BV structure 120(4) and AR 102 is from second part 122(5) of BV structure 120(4) through third part 108(8) of MD contact 106(4) and the instance of OC layer 116 into AR 102.

The instance of OC layer 114 facilitates a second current-path between BV structure 120(4) and AR 104. The second current-path between BV structure 120(4) and AR 104 is from second part 122(6) of BV structure 120(4) through third part 108(8) of MD contact 106(4) and the instance of OC layer 114 into AR 104.

According to another approach, a device counterpart to device 100E includes an MD contact which is a counterpart to MD contact 106(4), an active region which is a counterpart to AR 102 and a BV structure which is a counterpart to first part 122(4) of BV structure 120(4). Relative to the Y-axis, the BV structure according to the other approach does not extend significantly beyond the active region according to the other approach. The device counterpart according to the other approach has only one current-path between the other approach's counterparts to AR 102 and first part 122(4) of BV structure 120(4) of device 100F such that a total resistance between the other approach's counterparts to AR 102 and BV structure 120(4) is represented as R_bs, which causes the other approach to experience higher energy consumption, e.g., due to greater resistive losses, or the like. By contrast, device 100F (or other such embodiments as disclosed herein) has a substantially lower resistance due to the first, second and third current-paths between BV structure 120(4) and AR 102 and the first and second current-paths between BV structure 120(4) and AR 104, such that device 100F (or the like) experiences reduced energy consumption, e.g., due to reduced resistive losses, or the like, as compared to the other approach.

FIG. 2A is a layout diagram of a device 200A, in accordance with some embodiments.

Device 200A is an example of a device having an MD contact coupled to an active region and a BV structure. Device 200A is an example of a device having a WA_MD contact.

In FIG. 2A, device 200A is an inverter. Inverter 200A is an example of an D4 inverter (INVD4) inverter. The text string D4 is an acronym, where D is a unit of driving strength. As such, acronym D4 indicates that the cell region corresponding to inverter 200A has a current-driving/sourcing strength of 4D. In some embodiments, a value of unit driving strength D is determined by, e.g., the design rules and scale of the corresponding semiconductor process technology node.

The layout diagram of FIG. 2A is representative of a transistor-based device. Structures in the device are represented by patterns (also known as shapes) in the layout diagram. For simplicity of discussion, elements in the layout diagram of FIG. 2A (and also in other layout diagrams disclosed herein) will be referred to as if they are structures rather than patterns per se. For example, instances of 238 in FIG. 2A represent instances of a VD structure. In the following discussion, instances of element 238 are referred to as instances of VD structure 238 rather than as instances of VD pattern 238.

In FIG. 2A, section line I.A-I.A′ extends parallel to the Y-axis. In some embodiments, section line I.A-I.A′ of FIG. 2A corresponds to the cross-section of FIG. 1A. In some embodiments, section line I.A-I.A′ of FIG. 2A corresponds to the cross-section of FIG. 1B. In some embodiments, section line I.A-I.A′ of FIG. 2A corresponds to the cross-section of FIG. 1C. In some embodiments, section line I.A-I.A′ of FIG. 2A corresponds to the cross-section of FIG. 1D.

In FIG. 2A, as well as in other layout diagrams disclosed herein, an orthogonal Cartesian coordinate system is assumed in which first, second and third directions are, e.g., correspondingly parallel to the X-axis, the Y-axis and the Z-axis. A layout diagram per se is a top view. Shapes in the layout diagram are two-dimensional relative to, e.g., the X-axis and the Y-axis, whereas the device being represented is three-dimensional. As such, a shape in such layout diagrams is described as having a width/length relative to the X-axis and a height relative to the Y-axis. Relative to the Z-axis, e.g., a bottom/back side of a first component being represented in the layout diagram is stacked on a top/front side of a second component device being represented in the layout diagram, or a top/front back side of the first component is stacked, e.g., under a bottom/back side of the second component. In some embodiments, the first to third directions correspond to directions other than the X-axis, Y-axis and Z-axis.

Typically, relative to the Z-axis, the device is organized as a stack of layers in which are located corresponding structures, i.e., to which belong corresponding structures. Each shape in the layout diagram represents, more particularly, a component in a corresponding layer of the corresponding device. Also, typically, the layout diagram represents relative depth, i.e., positions along the Z-axis, of shapes and corresponding layers by superimposing a second shape on a first shape so that the second shape at least partially overlaps the first shape. For simplicity of illustration, some structures which have a first order of stacking along the Z-axis in the device are represented in the layout diagram using a second order of stacking along the Z-axis, i.e., a different/distorted stacking order. For example, in FIG. 2A, BV structure 220(1) is shown over AR 204 whereas correspondingly BV structure 120(1) is under AR 104 in FIG. 1A.

Layout diagrams vary in terms of the amount of detail represented. In some circumstances, selected layers of a layout diagram are combined/abstracted into a single layer, e.g., for purposes of simplification. Alternatively, and/or additionally, in some circumstances, not all layers of the corresponding device are represented, i.e., selected layers of the layout diagram are omitted, e.g., for simplicity of illustration. Alternatively, and/or additionally, in some circumstances, not all elements of a given depicted layer of the corresponding device are represented, i.e., selected elements of the given depicted layer of the layout diagram are omitted, e.g., for simplicity of illustration. FIG. 2A and the other layout diagrams disclosed herein are examples of layout diagrams in which selected layers and/or selected elements of depicted given layers, have been omitted. For example, instances of OC layer 110, instances of OC layer 112, or the like, are omitted from FIG. 2A. In some embodiments, the layout diagram of FIG. 2A is part of a larger layout diagram.

In FIG. 2A, inverter 200A includes: an instance of an N-type AR 202; an instance of a P-type AR 204; instances of gate lines/structures 230 and 232; MD contacts including MD contact 206(1) and MD contact 206(2); instances of VG structure 236; instances of VD structure 238; M0 segment 226(1) and M0 segment 226(2); instances of V0 structures 240; M1 segment 242(1) and M1 segment 242(2); BV structures including BV structure 220(1) and BV structure 220(2); and BM0 segments 228(1) and 228(2). Regarding inverter 200A, M1 segment 242(1) represents an input node, I. M1 segment 242(2) represents an output node, ZN.

Not all components are labeled with a reference number in FIG. 2A, for simplicity. For example, the MD contacts in FIG. 2A are not labeled with a reference number except for MD contacts 206(2) and 206(1). Also for example, the BV structures in FIG. 2A are not labeled with a reference number except for BV structures 220(1) and 220(2). In some embodiments, VG is an acronym for via-to-gate or via-on-gate or via-over-gate. In some embodiments, VD is an acronym for via-to-MD or via-on-MD or via-over-MD.

In FIG. 2A, gate lines/structures 232 align correspondingly with left and right boundaries of inverter 200A. In some embodiments, gate lines/structures 232 are replaced by corresponding isolation dummy gates (IDGs), discussed below.

In some embodiments, an IDG is a dielectric structure that includes one or more dielectric materials and functions as an electrical isolation structure. Accordingly, an IDG is not a structure that is electrically conductive and thus does not function, e.g., as an active gate of a transistor. An IDG includes one or more dielectric materials and functions as an electrical isolation structure. In some embodiments, an IDG is based on a gate line/structure as a precursor. In some embodiments, a method of forming an IDG includes: forming a gate line/structure; sacrificing/removing (e.g., etching) the gate line/structure to form a trench at least partially around the corresponding portion of the active region; (optionally) removing a portion or all of the corresponding active region that previously had been proximal to the gate line/structure to deepen the trench and thereby partially or completely divide the corresponding active region from extending beyond/outside the corresponding left or right side of the cell region relative to the X-axis; and then filling the trench with one or more dielectric materials such that the physical dimensions of the resultant electrical isolation structure, i.e., the IDG, are similar to the dimensions of the gate line/structure which was sacrificed. In some embodiments, an IDG is a dielectric feature that includes one or more dielectric materials (e.g., oxide, nitride, oxynitride, or other suitable materials), and functions as an isolation feature. In some embodiments, an IDG is a type of continuous polysilicon on oxide diffusion (OD) edge structure and is referred to as a type of CPODE structure.

FIG. 2B is a layout diagram of a device 200B, in accordance with some embodiments.

Device 200B is an example of a device having an MD contact coupled to an active region and a BV structure. Device 200B is an example of a device having a WA_MD contact.

Device 200B is an inverter. Inverter 200B of FIG. 2B is similar to inverter 200A of FIG. 2A. For brevity, the discussion will focus on differences of inverter 200B as compared to inverter 200A rather than on similarities. In some embodiments, inverter 200B is an example of a device that corresponds to section line I.E-I.E′ of FIG. 2B. Inverter 200B is an example of an INVD4 inverter.

In FIG. 2B, inverter 200B includes: an instance of an N-type AR 202; an instance of a P-type AR 204; instances of gate lines/structures 230 and 232; MD contacts including MD contact 206(4); instances of VG structure 236; instances of VD structure 238; M0 segment 226(3); instances of V0 structures 240; M1 segment 242(3); BV structures including BV structure 220(4); and BM0 segments 228(3) and 228(4). Regarding inverter 200B, M1 segment 242(3) represents an input node, I. BM0 segment 228(3) represents an output node, ZN.

Not all components are labeled with a reference number in FIG. 2B, for simplicity. For example, the MD contacts in FIG. 2B are not labeled with a reference number except for MD contact 206(4). Also for example, the BV structures in FIG. 2B are not labeled with a reference number except for BV structure 220(4).

In FIG. 2B, gate lines/structures 232 align correspondingly with left and right boundaries of inverter 200B. In some embodiments, gate lines/structures 232 are replaced by corresponding isolation dummy gates (IDGs), discussed below. Whereas each of inputs I and ZN are on the front side of inverter 200A in FIG. 2A, inputs I and ZN are correspondingly on the front side and back side of inverter 200B in FIG. 2B.

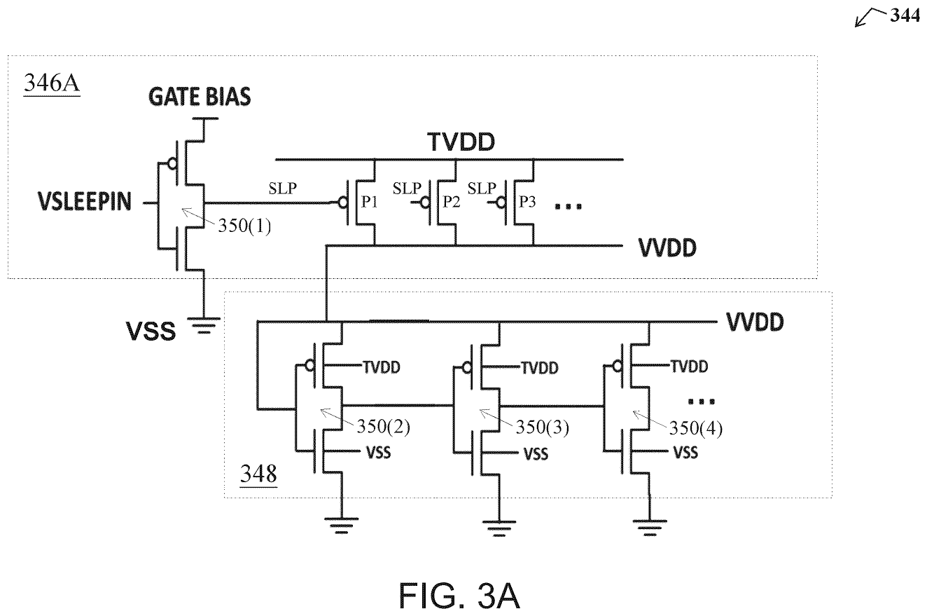

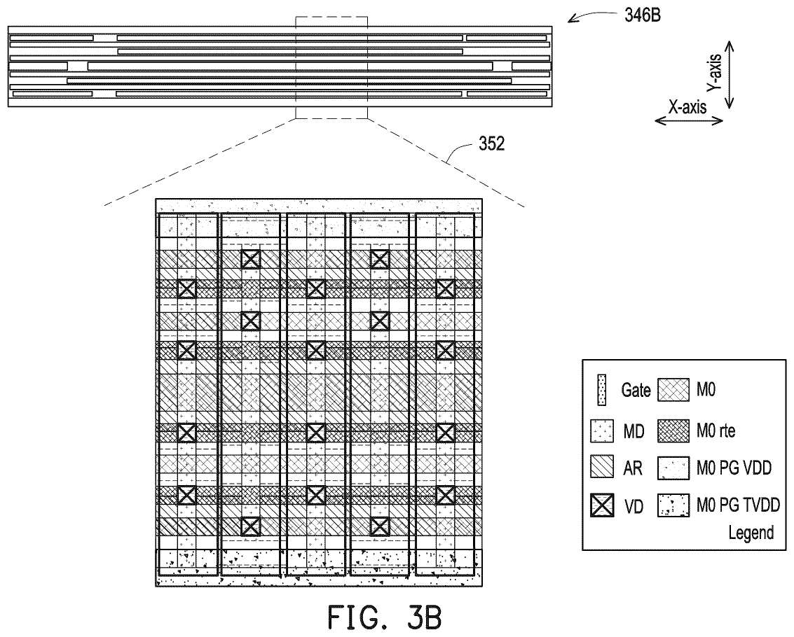

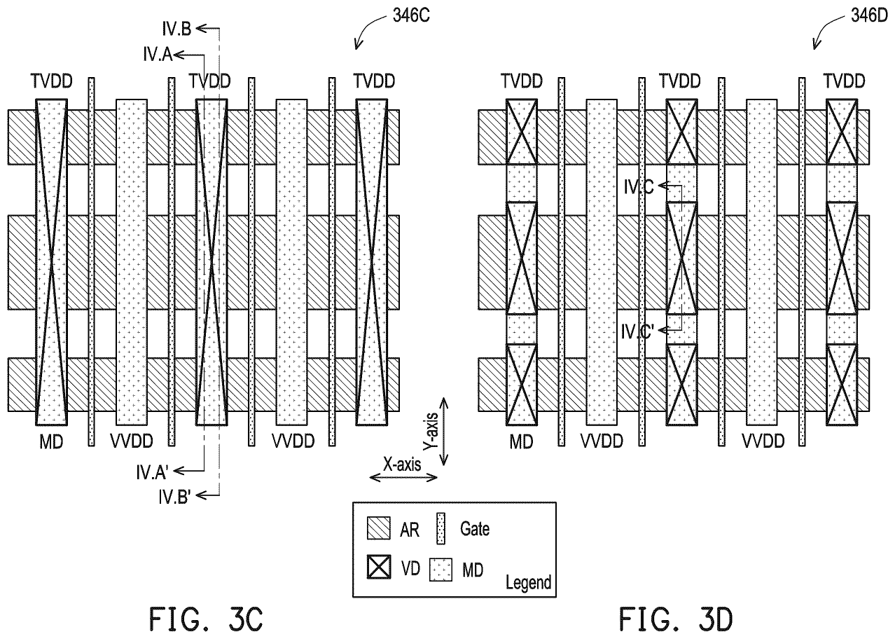

FIG. 3A is a schematic diagram 344, in accordance with some embodiments.

Schematic diagram 344 assumes reference voltages VDD and VSS, or the like. In FIG. 3A, a unswitched PG line configured for VDD is labeled as TVDD, whereas a switched line configured for VDD is labeled as VVVD. In some embodiments, TVDD is an acronym for true VDD. In some embodiments, VVDD is an acronym for virtual VDD.

Schematic diagram 344 includes a header circuit 346A and sleepy circuits 348. Header circuit 346A includes an inverter 350(1) and PFETs P1, P2 and P3. Inverter 350(1) is coupled between a gate bias voltage and VSS. Inverter 350(1) is configured to receive a sleep signal, VSLEEPIN, and generate an inverted version of the signal, SLP. PFETs P1, P2 and P3 are coupled in parallel between TVDD PG line and a VVDD PG line, and is configured to receive signal SLP at the gate thereof.

Sleepy circuits 348 include inverters 350(2), 350(3) and 350(4). Inverters 350(2), 350(3) and 350(4) are coupled in parallel between the VVDD PG line of and VSS. Inverter 350(2) is coupled to receive VVDD. The output of inverter 350(2) is coupled to the input of inverter 350(3). The output of inverter 350(3) is coupled to the input of inverter 350(4). In some embodiments, circuits 348 are referred to as sleepy circuits because, in effect, the voltage on VVDD PG line is selectively turned off or on by header circuit 346A such that circuits 348 correspondingly are put to sleep or left awake by header circuit 346A. When put to sleep, circuits 348 exhibit reduced leakage current.

FIG. 3B is a layout diagram of a device 346B, in accordance with some embodiments.

Device 346B is an example of a device having an MD contact coupled to an active region and a BV structure. Device 346B is an example of a device having a WA_MD contact.

Device 346B represents header circuits. In some embodiments, header circuits 346B of FIG. 3B correspond to header circuits 346A of FIG. 3A. A portion of header circuits 346B is shown in an exploded view 352.

FIGS. 3C-3D are layout diagrams of corresponding devices 346C and 346D, in accordance with some embodiments.

Each of devices 346C and 346D is an example of a device having an MD contact coupled to an active region and a BV structure. Each of devices 346C and 346D is an example of a device having a WA_MD contact.

Each of device 346C and 346D represents corresponding header circuits. Each of header circuits 346C and 346D is similar to exploded view 352 of header circuit 346B of FIG. 3B. For brevity, the discussion will focus on differences of each of header circuits 346C and 346D as compared to exploded view 352 of header circuit 346B of FIG. 3B rather than on similarities.

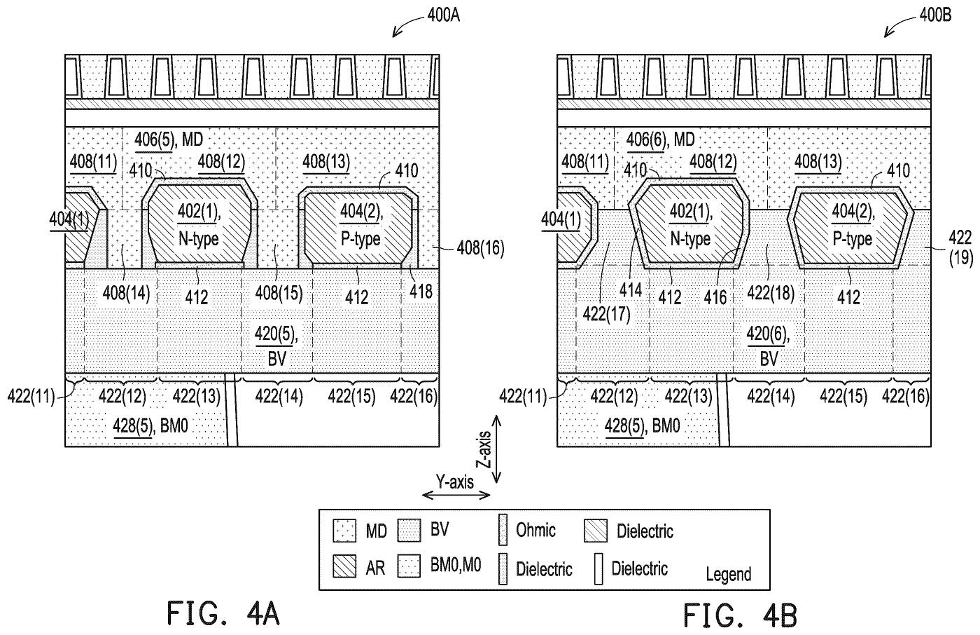

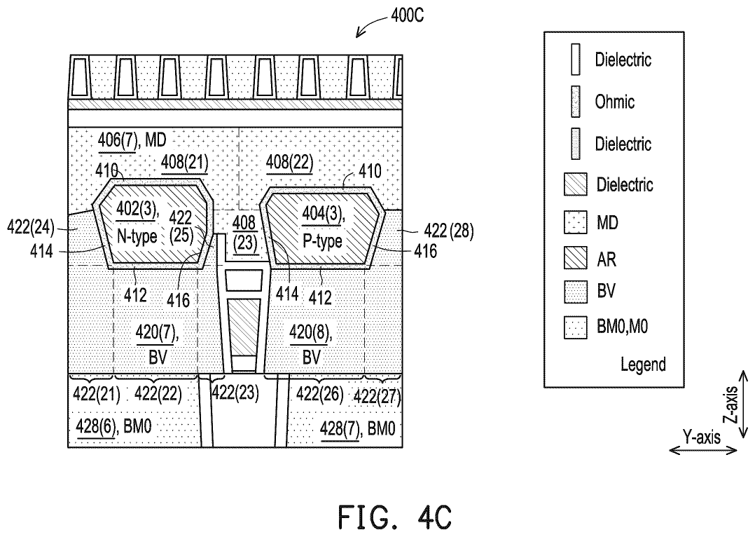

In some embodiments, section line IV.A-IV.A′ in FIG. 3C corresponds to header circuit 446A of FIG. 4A. In some embodiments, section line IV.B-IV.B′ in FIG. 3C corresponds to header circuit 446B of FIG. 4B. In some embodiments, section line IV.C-IV.C′ in FIG. 3D corresponds to header circuit 446C of FIG. 4C.

Each of FIGS. 3C-3D includes: three ARs; four gate lines/structures; five MD contacts; and three BV structures.

In FIG. 3C, relative to the Y-axis, each of the MD contacts extends across all three ARs. Each BV structure is correspondingly under and coupled to a corresponding one of the odd instances of the MD contacts. Relative to the Y-axis, lengths of the BV structures are substantially the same as lengths of the MD contacts. The even instances of the MD contacts are free from having an otherwise corresponding BV structure thereunder.

In FIG. 3D, relative to the Y-axis, each of the MD contacts extends across all three ARs. Each BV structure is correspondingly under and coupled to a corresponding one of the odd instances of the MD contacts. Relative to the Y-axis, a length of each of the BV structures is sufficient to extend significantly beyond top and bottom boundaries of the corresponding odd MD contact while also being free from underlapping any other ones of the MD contacts. The even instances of the MD contacts are free from having an otherwise corresponding BV structure thereunder.

FIG. 4A is a cross-sectional view of a device 400A, in accordance with some embodiments.

Device 400A is an example of a device having an MD contact coupled to an active region and a BV structure. Device 400A is an example of a device having a WA_MD contact.

Device 400A of FIG. 4A is similar to device 100E of FIG. 1E. For brevity, the discussion will focus on differences of device 400A as compared to device 400E rather than on similarities. In some embodiments, device 400A is an example of a device that corresponds to section line IV.A-IV.A′ of FIG. 3C; from the perspective of the Y-axis, it is noted that the relative width of AR 402(1) in FIG. 4A is narrower than the relative width of the middle AR in FIG. 3C, for simplicity of illustration.

Device 400A of FIG. 4A includes: N-type AR 402(1) and P-type ARs 404(1) and 404(2); instances of OC layers 410 and 412; instances of dielectric structures and layers including dielectric structures 418; MD contact 406(5); BV structure 420(5); and BM0 segment 428(5). In some embodiments, the instances of dielectric structures 418 are replaced by corresponding instances of OC layer 114 and instances of OC layer 116.

MD contact 406(5) includes parts 408(11)-408(16). Part 408(11) is on AR 404(1). Part 408(12) is on AR 402(1). Part 408(13) is on AR 404(2). Part 408(14) is between AR 404(1) and AR 402(1). Part 408(15) is between AR 402(1) and AR 404(2). Part 408(16) is at the right side of AR 404(2).

BV structure 420(5) includes parts 422(11)-422(16). Part 422(11) is under AR 404(1). Part 422(12) is under part 408(14) of MD contact 406(5). Part 422(13) is under AR 402(1). Part 422(14) is under part 408(15) of MD contact 406(5). Part 422(15) is under AR 404(2). Part 422(16) is under part 408(16) of MD contact 406(5).

FIG. 4B is a cross-sectional view of a device 400B, in accordance with some embodiments.

Device 400B is an example of a device having an MD contact coupled to an active region and a BV structure. Device 400B is an example of a device having a WA_MD contact.

Device 400B of FIG. 4B is similar to device 400A of FIG. 4A. For brevity, the discussion will focus on differences of device 400B as compared to device 400A rather than on similarities. In some embodiments, device 400B is an example of a device that corresponds to section line IV.B-IV.B′ of FIG. 3C; from the perspective of the Y-axis, it is noted that the relative width of AR 402(1) in FIG. 4B is narrower than the relative width of the middle AR in FIG. 3C, for simplicity of illustration.

As compared to device 400A of FIG. 4A, device 400B of FIG. 4B further includes instances of OC layer 414 and instances of OC layer 416. In device 400B, the instance of OC layer 414 and the instance of OC layer 416 correspondingly replace dielectric structures 418 of device 400A. The instances of OC layer 414 correspondingly are on/against the left side of each of AR 402(1) and AR 404(2). The instances of OC layer 416 correspondingly are on/against the right side of each of AR 404(1), AR 402(1) and AR 404(2).

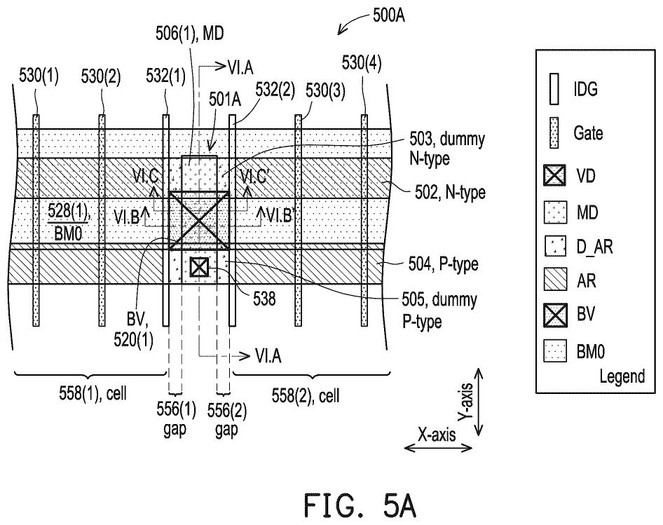

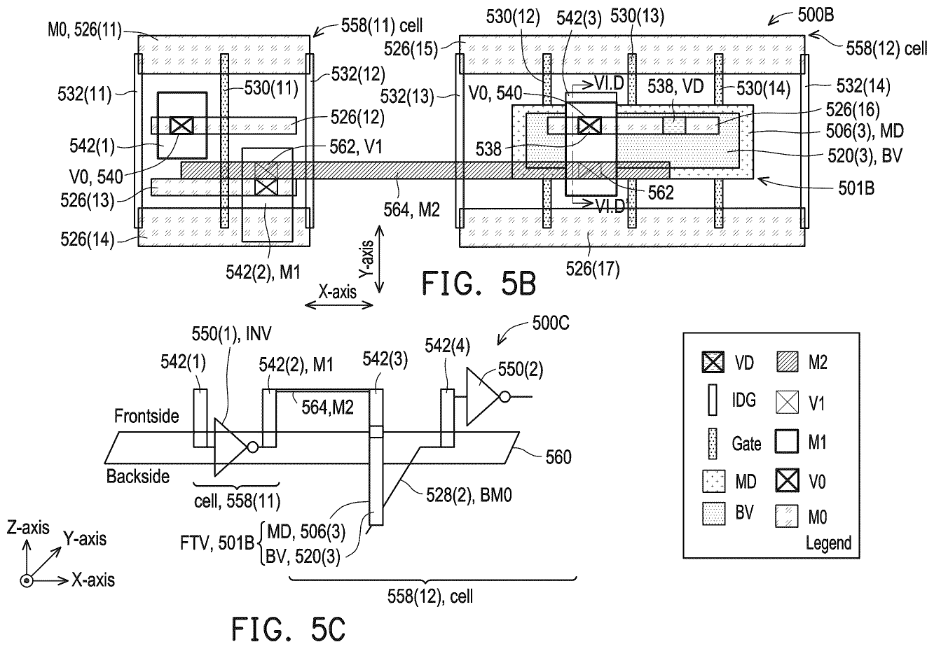

As compared to device 400A of FIG. 4A, device 400B of FIG. 4B further includes parts 422(17) and 422(18) resulting in an enlarged version of BV structure 420(5) being shown in FIG. 4B. The enlarged version shown in FIG. 5B of BV structure 420(5) is assigned reference number 420(6) in FIG. 4B. In device 400B, in terms of occupied space, parts 422(17)-422(19) of BV structure 420(6) effectively replace corresponding parts 408(14)-408(16) of MD contact 406(5) of FIG. 4B, resulting in a truncated version of MD contact 406(5). The truncated version of MD contact 406(5) in FIG. 4B is assigned reference number 406(6) in FIG. 4B.

In FIG. 4B, the instances of OC layer 414 facilitate additional corresponding current-paths between BV structure 420(6) and ARs 404(1), 402(1)) and 404(2). The instances of OC layer 416 facilitate additional corresponding current-paths between BV structure 420(5) and ARs 404(1), 402(1) and 404(2).

FIG. 4C is a cross-sectional view of a device 400C, in accordance with some embodiments.

Device 400C is an example of a device having an MD contact coupled to an active region and a BV structure. Device 400C is an example of a device having a WA_MD contact.

Device 400C of FIG. 4C is similar to device 100C of FIG. 1C. For brevity, the discussion will focus on differences of device 400C as compared to device 100C rather than on similarities. In some embodiments, device 400C is an example of a device that corresponds to section line IV.C-IV.C′ of FIG. 3D

Device 400C of FIG. 4C includes: N-type AR 402(3); P-type AR 404(3); instances of dielectric structures and layers; instances of OC layer 414; instances of OC layer 416; MD contact 406(7); BV structures 420(7) and 420(8); and BM0 segments 428(6) and 428(7). MD contact 406(7) includes parts 408(21)-408(23). BV structure 420(7) includes parts 422(21)-422(25). BV structure 420(8) includes parts 422(26)-422(28).

Regarding MD contact 406(7), a majority of part 408(21) is on and coupled AR 402(3) through an instance of OC layer 410. A majority of part 408(22) is on and coupled AR 404(3) through an instance of OC layer 410. Part 408(23) is between AR 402(3) and AR 404(3). The right side of part 408(21) abuts the left side of part 408(22). A lower left portion of part 408(21) is on and coupled to part 422(24) of BV structure 420(7). A lower right portion of part 408(21) is on and coupled to part 408(23). A lower left portion of part 408(22) is on and coupled to part 408(23). A portion of part 408(23) is against and coupled to AR 402(3) through an instance of OC layer 416. A portion of part 408(23) is coupled to part 422(25) of BV structure 420(7). A portion of part 408(23) is against and coupled to AR 404(3)) through an instance of OC layer 414.

Regarding BV structure 420(7), part 422(24) is against and coupled to AR 402(3) through an instance of OC layer 414. Part 422(22) is under and coupled to AR 402(3) through an instance of OC layer 412. The left side of part 422(22) abuts the right side of part 422(21). Part 422(24) is on part 422(21). The right side of part 422(22) abuts the left side of part 422(23). Part 422(25) is on part 422(23).

Regarding BV structure 420(8), part 422(26) is under and coupled to AR 404(3) through an instance of OC layer 412. The right side of part 422(26) abuts the left side of part 422(27). Part 422(28) is on part 422(27). Part 422(28) is against and coupled to AR 404(3) through an instance of OC layer 416.

FIG. 5A is a layout diagram of device 500A, in accordance with some embodiments.

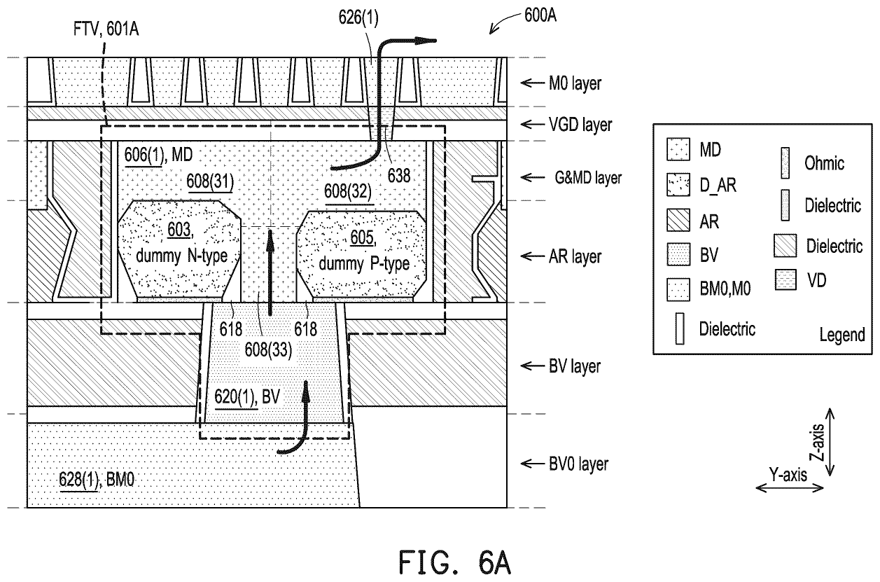

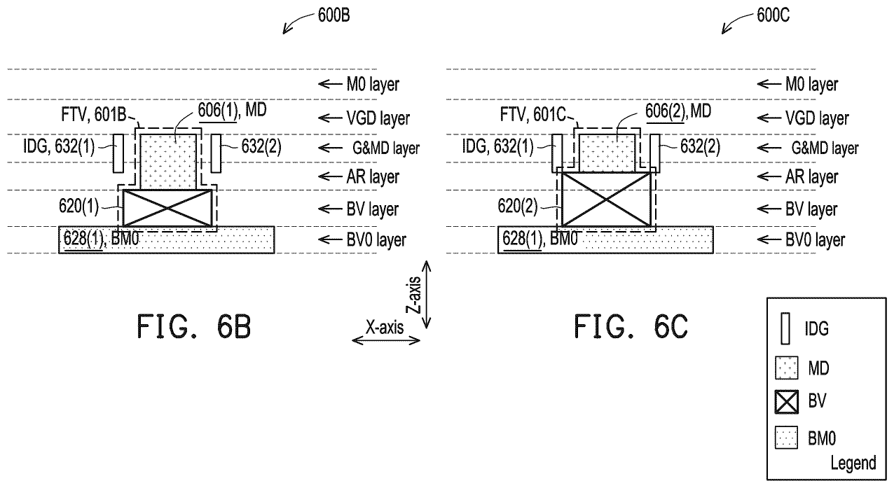

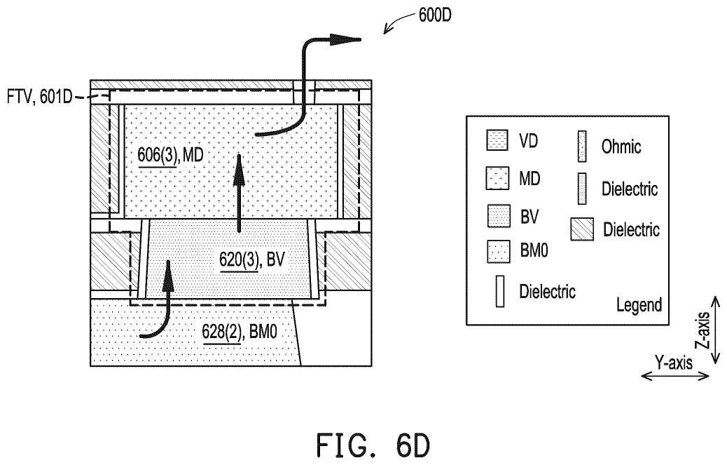

Device 500A is a wiring arrangement including a feedthrough via (FTV) 501A. In FIG. 5A, section line VI.A-VI.A′ extends parallel to the Y-axis. In some embodiments, section line VI.A-VI.A′ of FIG. 5A corresponds to the cross-section of FIG. 6A. In FIG. 5A, section line VI.B-VI.B′ extends parallel to the Y-axis. In FIG. 5A, section line VI.B-VI.B′ extends parallel to the X-axis. In some embodiments, section line VI.B-VI.B′ of FIG. 5A corresponds to the cross-section of FIG. 6B. In FIG. 5A, section line VI.D-VI.C′ extends parallel to the X-axis. In some embodiments, section line VI.D-VI.D′ of FIG. 5A corresponds to the cross-section of FIG. 6C.

Device 500A includes: an N-type AR 502; a P-type AR 504; gate lines/structures 530(1)-530(4); IDGs 532(1)-532(2); an MD contact 506(1); a VD structure 538; a BV structure 520(1); and a BM0 segment 528(1). In some embodiments, at least one of IDs 532(1) and 532(2) is replaced with a corresponding gate line/structure.

N-type AR 502 includes a dummy portion 503 referred to herein as N-type dummy AR 503. P-type AR 504 includes a dummy portion 505 referred to herein as P-type dummy AR 505. In some embodiments, a dummy AR is a portion of a given AR that is electrically isolated from other portions of the given AR. In FIG. 5A, dummy AR 503 is isolated from other portions of AR 502 by IDGs 532(1)-532(2). Similarly, dummy AR 505 is isolated from other portions of AR 504 by IDGs 532(1)-532(2). In some embodiments; IDGs 532(1)-532(2) are replaced by gate lines/structures; in some of such embodiments, dummy AR 503 is a result of different doping as compared to the doping other portions of AR 502 and dummy AR 505 is a result of different doping as compared to the doping of other portions of AR 504.

Relative to the X-axis, adjacent gate lines/structures 530(1)-530(4) and IDGs 532(1)-532(2) are separated from each other by a uniform distance. In some embodiments, the uniform distance represents one contacted poly pitch (CPP) for the corresponding semiconductor process technology node. For example, each of (A) gate lines/structures 530(1) and 530(2), (B) gate line/structure 530(2) and IDG 532(1), and (C) IDGs 532(1) and 532(2) are separated from each other by one CPP. In some embodiments, CPP is an acronym for contacted poly pitch, where the word ‘poly’ does not necessarily imply that the gate lines/structures re to be formed of polysilicon but instead represents a historical convenience, i.e., because gate structures in ICs manufactured according to a predecessor semiconductor process technology node often were formed of polysilicon.

In FIG. 5A, FTV 501A includes MD contact 506(1) and BV structure 520(1). FTV 501A extends parallel to the Y-axis. FTV 501A facilitates a current-path from BM0 segment 528(1) to M0 segment 526 through BV structure 520(1), MD contact 506(1) and VD structure 538.

Relative to the X-axis, left and right sides of each of MD contact 506(1) and BV structure 520(1) correspondingly extend oppositely and parallel to the X-axis so as to be proximal correspondingly to IDGs 532(1) and 532(2). Relative to the X-axis, the left and right sides of each of MD contact 506(1) and BV structure 520(1)) are free from extending substantially beyond IDGs 532(1) and 532(2). Assuming that IDGs 532(1) and 532(2) are separated from each other by one CPP relative to the X-axis, a width of FTV 501A is approximately one CPP or smaller.

Relative to the X-axis: IDG 532(1) represents a right side boundary of a cell region 558(1); and IDG 532(2) represents a left side boundary of a cell region 558(2). As such, FTV 501A is in an inter-cell gap between cell regions 558(1) and 558(2).

According to another approach, a device counterpart to device 500A includes a type of FTV which is a counterpart to FTV 501A and gate lines/structures which are corresponding counterparts to IDGs 230 and 232. Relative to the X-axis, the other approach's counterpart FTV extends substantially beyond each of the other approach's counterpart gate lines/structures, which consumes a substantial area and reduces device density. By contrast, FTV 501A or the like is free from extending substantially beyond IDGs 532(1) and 532(2) such that device 500A or the like consumes a smaller area and increases device density as compared to the other approach.

FIG. 5B is a layout diagram of device 500B, in accordance with some embodiments.

Device 500B is a wiring arrangement including a feedthrough via (FTV) 501(B). In FIG. 5B, section line VI.D-VI.D′ extends parallel to the Y-axis. In some embodiments, section line VI.E-VI.E′ of FIG. 5B corresponds to the cross-section of FIG. 6E.

Device 500B includes: gate lines/structures 530(11)-530(14); IDGs 532(11)-532(14); an MD contact 506(3); instances of a VD structure 538; M0 segments 626(11)-626(17); instances of a V0 structure 540; M1 segments 542(1)-542(3); instances of a V1 structure 562; an M2 segment 564; and a BV structure 520(3). In some embodiments, at least one of IDs 532(11)-532(14) is replaced with a corresponding gate line/structure.

In FIG. 5B, FTV 501B includes MD contact 506(3) and BV structure 520(3). FTV 501B extends parallel to the Y-axis. FTV 501B facilitates a current-path from a BM0 segment (see 528(2) FIG. 5B, 628(2) FIG. 6D) to M0 segment 526(16) through BV structure 520(3), MD contact 506(3) and instances of VD structure 538. Furthermore, cell region 558(11) is coupled to cell region 558(2) through an inter-cell coupling represented by a current-path that includes: M0 segment 526(16); an instance of V0 structure 540; M1 segment 542(3); an instance of V1 structure 562; M2 segment 564; another instance of V1 structure 562; M1 segment 542(2); another instance of V0 structure 540; and M0 segment 526(13).

Relative to the X-axis, left and right sides of each of MD contact 506(3) and BV structure 520(3) correspondingly extend oppositely and parallel to the X-axis so as to be proximal correspondingly to gate lines/structures 532(12) and 530(13). Relative to the X-axis, the left and right sides of each of MD contact 506(3) and BV structure 520(3)) are free from extending substantially beyond gate lines/structures 532(12) and 530(13). Relative to the X-axis: IDGs 532(11) and 532(12) correspondingly represent left and right side boundaries of cell region 558(11); and IDGs 532(13) and 532(14) correspondingly represent left and right side boundaries of cell region 558(12).

According to another approach, a device counterpart to device 500A includes a type of FTV which is a counterpart to FTV 501B and gate lines/structures which are corresponding counterparts togate lines/structures 532(12) and 530(13). Relative to the X-axis, the other approach's counterpart FTV extends substantially beyond each of the other approach's counterpart gate lines/structures, which consumes a substantial area and reduces device density. By contrast, FTV 501B or the like is free from extending substantially beyond gate lines/structures 532(12) and 530(13) such that device 500B or the like consumes a smaller area and increases device density as compared to the other approach.

FIG. 5C is a combination schematic and three-quarter perspective diagram of a device 500C, in accordance with some embodiments.

Device 500C is an alternate representation of device 500B of FIG. 5B. In comparison to FIG. 5B, FIG. 5C further includes: a representation of a BM0 segment 528(2); representations of inverters 550(1) and 550(2); and a representation of an imaginary reference plane 560 parallel to the X-Y plane. Relative to the Z-axis, device 500C is described as having a front side above, and a back side below, reference plane 560.

FIG. 6A is a cross-sectional view of a device 600A, in accordance with some embodiments.

Device 600A is an example of a device having an FTV structure comprised of an MD contact coupled to a BV structure. Device 600A of FIG. 6A is similar to device 100E of FIG. 1E. For brevity, the discussion will focus on differences of device 600A as compared to device 100E rather than on similarities. In some embodiments, device 600A is an example of a device that corresponds to section line IV.A-IV.A′ of FIG. 5A, where section line IV.A-IV.A′ is parallel to the Y-axis.

Device 600A includes: a dummy N-type AR 603; a dummy P-type AR 605; MD contact 606(1); VD structure 638; M0 segments including M0 segment 626(1); BV structure 620(1); and BM0 segment 628(1).

In FIG. 6A, FTV 601A includes MD contact 606(1) and BV structure 620(1). MD contact 606(1) includes parts 608(31), 608(32) and 608(33).

FIG. 6B is a cross-sectional view of a device 600B, in accordance with some embodiments.

Device 600B is an example of a device having an FTV structure comprised of an MD contact coupled to a BV structure. Device 600B of FIG. 6B is similar to device 600A of FIG. 6A. For brevity, the discussion will focus on differences of device 600B as compared to device 600A rather than on similarities. In some embodiments, device 600B is an example of a device that corresponds to section line IV.B-IV.B′ of FIG. 5A, where section line IV.B-IV.B′ is parallel to the X-axis.

Device 600B includes: IDGs 632(1)-632(2); MD contact 606(1); BV structure 620(1); and BM0 segment 628(1). Relative to the X-axis, the left and right sides of BV structure 620(1)) are free from extending substantially beyond IDGs 632(1) and 632(2).

FIG. 6C is a cross-sectional view of a device 600C, in accordance with some embodiments.

Device 600C is an example of a device having an FTV structure comprised of an MD contact coupled to a BV structure. Device 600C of FIG. 6C is similar to device 600B of FIG. 6B. For brevity, the discussion will focus on differences of device 600C as compared to device 600B rather than on similarities. In some embodiments, device 600C is an example of a device that corresponds to section line IV.C-IV.C′ of FIG. 5A, where section line IV.C-IV.C′ is parallel to the X-axis.

Device 600C includes MD contact 606(2) and BV structure 620(2) whereas device 600B includes MD contact 606(1) and BV structure 620(1). Relative to the Z-axis, BV structure 620(2) extends substantially into the AR layer whereas BV structure 620(1) does not extend substantially into the AR layer. Correspondingly, relative to the Z-axis, MD contact 606(2) does not as far into the AR layer as MD contact 606(1). As such, in some respects, FIG. 6C relates to FIG. 6B in a manner somewhat similar to how FIG. 1C relates to FIG. 1A.

FIG. 6D is a cross-sectional view of a device 600D, in accordance with some embodiments.

Device 600D is an example of a device having an FTV structure comprised of an MD contact coupled to a BV structure. In some embodiments, device 600D is an example of a device that corresponds to section line IV.D-IV.D′ of FIG. 5B, where section line IV.D-IV.D′ is parallel to the Y-axis.

Device 600D includes: MD contact 606(3); VD structure 638; BV structure 620(3); and BM0 segment 628(2). In FIG. 6D, FTV 601D includes MD contact 606(3) and BV structure 620(3).

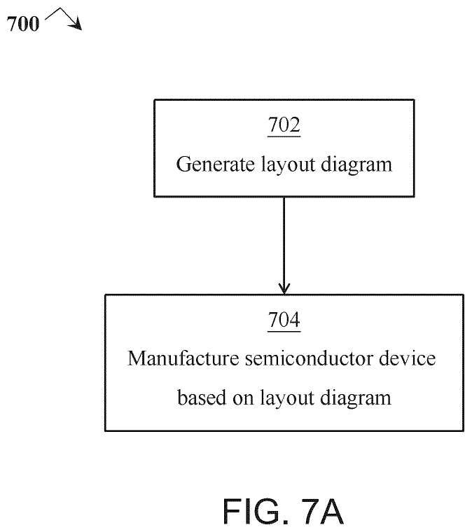

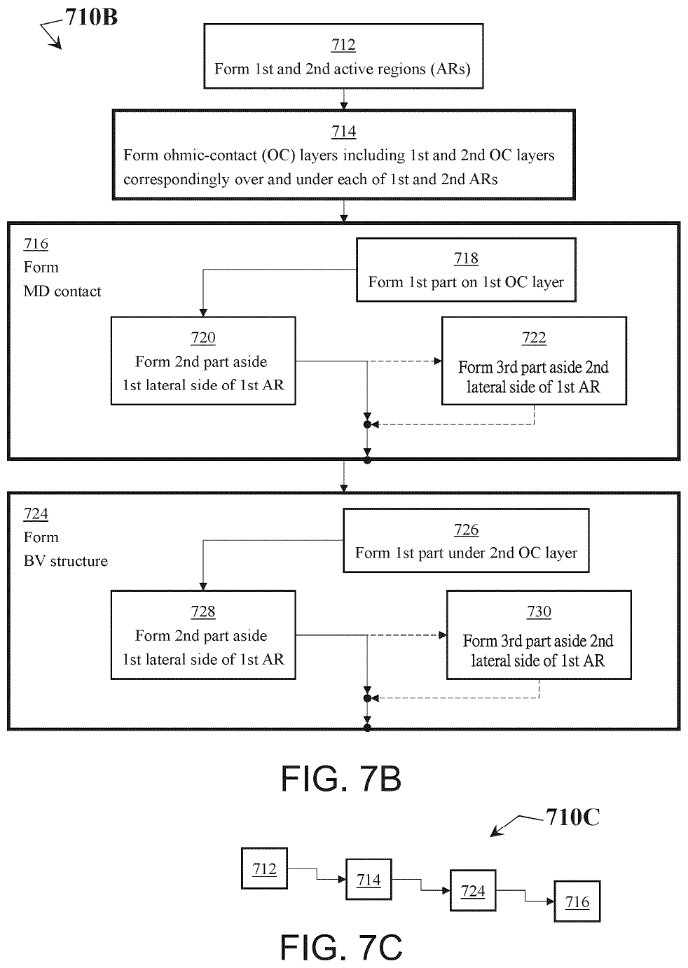

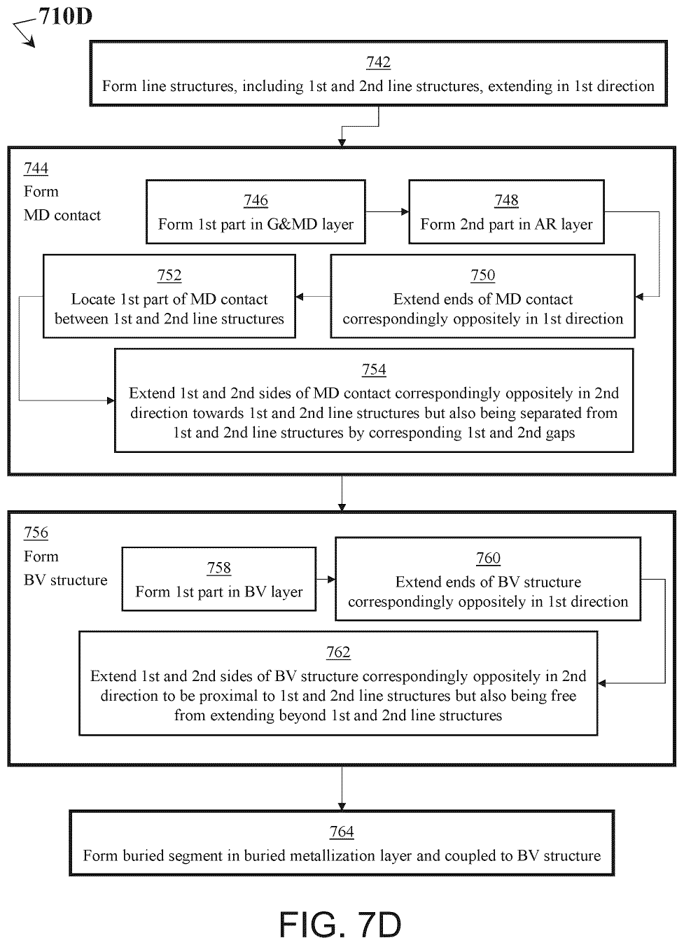

FIG. 7A is a flowchart 700 of a method of manufacturing a device, in accordance with some embodiments.

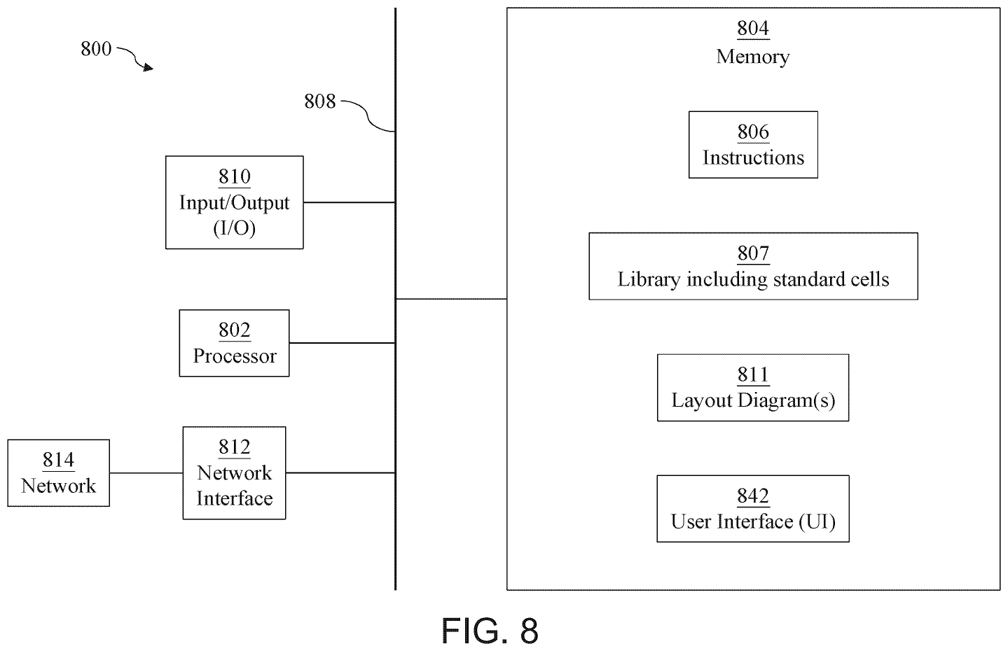

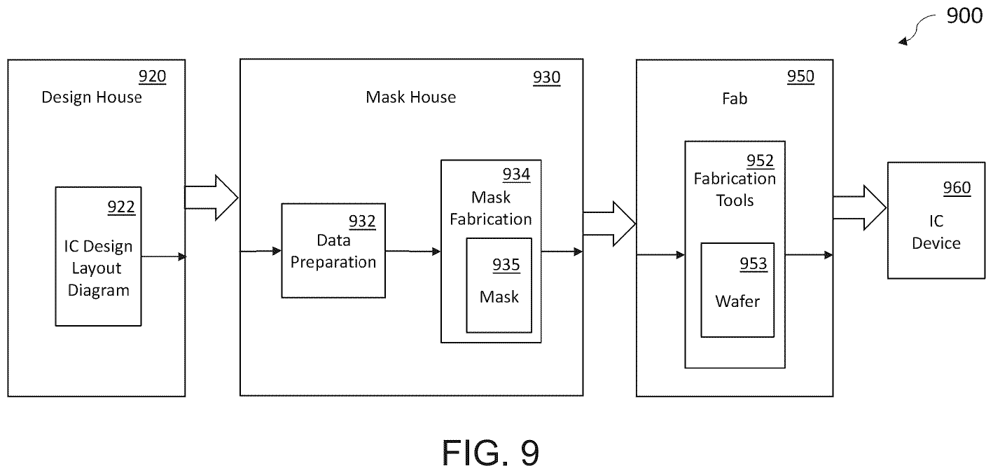

The method of flowchart (flow diagram) 712A is implementable, for example, using EDA system 800 (FIG. 8, discussed below) and an IC manufacturing system 900 (FIG. 9, discussed below), in accordance with some embodiments. Examples of a device which can be manufactured according to the method of flowchart 700 include devices disclosed herein, devices based on the layout diagrams disclosed herein, or the like.

In FIG. 7A, the method of flowchart 700 includes blocks 702-704. At block 702, a layout diagram is generated which, among other things, includes one or more of layout diagrams disclosed herein, layout diagrams corresponding to one or more of the devices disclosed herein, or the like. Block 702 is implementable, for example, using EDA system 800 (FIG. 8, discussed below), in accordance with some embodiments. From block 702, flow proceeds to block 704.

At block 704, based on the layout diagram, at least one of (A) one or more photolithographic exposures are made or (b) one or more photolithography masks are fabricated or (C) one or more components in a layer of a device, e.g., a device is fabricated. Sec discussion below of IC manufacturing system 900 in FIG. 9 below.

FIG. 7B is a flowchart 710B of a method of fabricating a device, in accordance with some embodiments.

Flowchart 710B is an example of block 704 of FIG. 7A. Flowchart 710B includes blocks 712-730. Examples provided in the context of flowchart 710B assume first, second and third orthogonal directions that are, e.g., correspondingly parallel to the X-axis, the Y-axis and the Z-axis. The method of flowchart 710B is implementable, for example, using IC manufacturing system 900 (FIG. 9, discussed below), in accordance with some embodiments. Examples of a device which can be manufactured according to the method of flowchart 710B include the devices disclosed herein, devices based on the layout diagrams disclosed herein, or the like.

At block 712, first and second active regions are formed. Examples of the first active region include AR 102 of FIGS. 1A-1F, AR 402(1)-402(3) of FIGS. 4A-4C, AR 502, or the like. Examples of the second active region include AR 104 of FIGS. 1A-IF, AR 404(1)-404(3) of FIGS. 4A-4C, AR 504 of FIG. 4A, or the like. From block 712, flow proceeds to block 714.

At block 714, ohmic-contact (OC) layers are formed including forming a first ohmic-contact layer on, and coupled to, a front side of a first portion of the first active region, and forming a second ohmic-contact layer on, and coupled to, a back side of the first portion of the first active region. From block 714, flow proceeds to block 716.

At block 716, an MD contact is formed. Examples of the MD contact include MD contacts 106(1)-106(4) correspondingly of FIGS. 1A-IF, MD contacts 406(5)-406(7) correspondingly of FIGS. 4A-4C, MD contact 506(1) of FIG. 5A, or the like. Block 716 includes blocks 718-720. Inside block 716, flow proceeds to block 718.

At block 718, a first part of the MD contact is formed on the first OC layer. Examples of the first part of the MD contact include: parts 108(1) and 108(3) of FIGS. 1A-1C, part 108(6) of FIGS. 1E-IF, part 408(12) of FIGS. 4A-4B, part 408(21) of FIG. 4C, or the like. From block 718, flow proceeds to block 720.

At block 720, a second part of the MD contact is formed aside a first lateral side of the first AR. Examples of the second part of the MD contact include: parts 108(2) and 108(4) of FIGS. 1A-IC, part 408(14) of FIG. 4A, part 408(23) of FIG. 4C, or the like. From block 720, flow proceeds out of block 716 to block 724. As an option in some embodiments, however, flow proceeds from block 720 to block 722, the option being indicated in FIG. 7B by a phantom/dashed arrow.

At block 722, a third part of the MD contact is formed aside a second lateral side of the first AR. Examples of the third part of the MD contact include: part 408(15) of FIG. 4A, or the like. From block 722, flow proceeds to out of block 716 to block 724.

At block 724, a BV structure is formed. Examples of the BV structure include BV structures 120(1)-120(4) correspondingly of FIGS. 1A-IF, BV structures 420(5)-420(8) correspondingly of FIGS. 4A-4C, BV structure 520(1) of FIG. 5A, or the like. Block 724 includes blocks 726-730. Inside block 724, flow proceeds to block 726.

At block 726, a first part of the BV structure is formed under the second OC layer. Examples of the first part of the BV structure include: parts 122(1), 122(3) and 122(5) correspondingly of FIGS. 1A-IF, parts 422(13) and 422(15) of FIGS. 4A-4B, parts 422(22) and 422(26) of FIG. 4C, or the like. From block 726, flow proceeds to block 728.

At block 728, a second part of the BV structure is formed aside the first lateral side of the first AR. Examples of the second part of the BV structure include: parts 122(2) and 122(4)-122(4) correspondingly of FIGS. 1A-ID, part 122(5) of FIGS. 1E-IF, parts 422(12) and 422(15) of FIGS. 4A-4B, parts 422(21) and 422(27) of FIG. 4C, or the like. From block 728, flow proceeds out of block 724. As an option in some embodiments, however, flow proceeds from block 728 to block 730, the option being indicated in FIG. 7B by a phantom/dashed arrow.

At block 730, a third part of the BV structure is formed aside the second lateral side of the first AR. Examples of the third part of the BV structure include: parts 422(15) and 422(16) of FIGS. 4A-4B, part 422(23) of FIG. 4C, or the like.

In some embodiments, at block 714, the forming a first OC layer includes forming a silicide layer, and the forming a second ohmic-contact layer includes forming a silicide layer.

In some embodiments, at block 714, the forming ohmic-contact layers further includes: (i) forming a third OC layer on, and coupled to, the first lateral side of the first portion of the first active region; or (ii) forming a fourth OC layer on, and coupled to, the second lateral side of the first portion of the first active region. Examples of the third OC layer include: the instances of OC layer 114 on the left side of AR 102 of FIGS. 1B and 1C and on the left side of AR 104 in FIG. 1F, the instances of OC layer 414 on the left side of ARs 402(1) and 404(2) in FIG. 4B and on the left side of AR 404(3) in FIG. 4C, or the like. Examples of the fourth OC layer include the instances of OC layer 116 on the right side of AR 104 of FIGS. 1B and 1C and on the right side of AR 104 in FIG. 1F, the instances of OC layer 416 on the right side of ARs 402(1) and 404(2) in FIG. 4B and on the right side of AR 404(3) in FIG. 4C, or the like. In such embodiments: block 720 correspondingly further includes coupling the second part of the MD contact to the third ohmic contact layer; or block 722 includes: coupling the third part of the MD contact to the fourth ohmic-contact layer.

In some embodiments, block 714 includes (i) and (ii). In some embodiments, at block 714, the forming a third OC layer includes forming a silicide layer, and the forming a fourth ohmic-contact layer includes forming a silicide layer.

In some embodiments, after block 712 and before block 714, flowchart 710B includes (i) forming a first dielectric layer (e.g., 118(1), instances of 418, or the like) on the first lateral side of the first active region, the second part of the MD contact being on the first dielectric layer; or (ii) forming a second dielectric layer (e.g., 118(2), instances of 418, or the like) on the second lateral side of the first active region, the third part of the MD contact being on the second dielectric layer. In some embodiments, block 712 includes (i) and (ii).

In some embodiments, block 720 includes extending the second part (e.g., 108(2), or the like) of the MD contact to be on, and coupled to, the upper surface of the second part (e.g., 122(2), or the like) of the BV structure; or block 722 includes extending the third part (e.g., 408(15), or the like) of the MD contact to be on, and coupled to, the upper surface of the third part (e.g., 422(14), or the like) of the BV structure.

In some embodiments, block 720 includes extending the second part (e.g., 108(2), or the like) of the MD contact substantially below the upper surface of the first portion of the first active region so as to be on, and coupled to, the upper surface of the second part (e.g., 122(2), or the like) of the BV structure; or extending the third part (e.g., 408(15), or the like) of the MD contact substantially below the upper surface of the first portion of the first active region so as to be on, and coupled to, the upper surface of the third part (e.g., 422(14), or the like) of the BV structure.

In some embodiments, block 716 includes blocks 720 and 722, and further includes: a block 723(1) (not shown in FIG. 7B) that includes forming a fourth part (e.g., 408(13)), of the MD contact on the third ohmic-contact layer of the first portion of the second active region resulting in coupling therebetween; and a block 723(2) (not shown in FIG. 7B) that includes forming a fifth part (e.g., 408(16, or the like) of the MD contact aside the second lateral side of the first portion of the second active region. In such embodiments, block 724 includes blocks 728 and 730 and further includes: a block 725(1) (not shown in FIG. 7B) that includes forming a third part (e.g., 422(14), or the like) of the BV structure under, and coupled to, the third part (e.g., 408(15), or the like) of the MD contact; a block 725(2) (not shown in FIG. 7B) that includes forming a fourth part (e.g., 422(15), or the like) of the BV structure under, and coupled to, the fourth ohmic-contact layer; and a block 725(3) (not shown in FIG. 7B) that includes forming a fifth part (e.g., 422(16), or the like) of the BV structure under, and coupled to, the fifth part of the MD contact.

In some embodiments: block 720 includes extending the second part (e.g., 408(14), or the like) of the MD contact to be on, and coupled to, the upper surface of the second part (e.g., 422(12), or the like) of the BV structure; block 725(1) includes extending the third part (e.g., 408(15), or the like) of the MD contact to be on, and coupled to, the upper surface of the third part (e.g., 422(14), or the like) of the BV structure; or block 725(3) extending the fifth part (e.g., 408(16), or the like) of the MD contact to be on, and coupled to, the upper surface of the fourth part (e.g., 422(16), or the like) of the BV structure.

In some embodiments, a lower surface at the back side of each of the first and second active regions is substantially planar, and block 724 further includes: extending an upper surface of the second part (e.g., 422(12)) of the BV structure (e.g., 420(5)) substantially above the lower surface of each of the first and second active regions; extending an upper surface of the third part (e.g., 422(14)) of the BV structure (e.g., 420(5)) substantially above the lower surface of each of the first and second active regions; or extending an upper surface of the fifth part (e.g., 422(16)) of the BV structure (e.g., 420(5)) substantially above the lower surface of each of the first and second active regions.

In FIG. 7B, without taking into consideration smaller blocks that are internal to larger blocks, e.g., smaller blocks 718-722 are internal to larger block 714, flowchart 710B shows the following sequence: block 712→block 714→block 716→block 724.

FIG. 7C is a flowchart 710C of a method of manufacturing a device, in accordance with some embodiments.

The method of flowchart (flow diagram) 710C is implementable, for example, using EDA system 800 (FIG. 8, discussed below) and an IC manufacturing system 900 (FIG. 9, discussed below), in accordance with some embodiments. Examples of a device which can be manufactured according to the method of flowchart 710C include devices disclosed herein, devices based on the layout diagrams disclosed herein, or the like.

Flowchart 710C of FIG. 7C is similar to flowchart 710B of FIG. 7B. For brevity, the discussion will focus on differences of flowchart 710C as compared to flowchart 710B rather than on similarities.

Flowchart 710C includes the same blocks at flowchart 712B. For simplicity of illustration, however, flowchart 710C does not show smaller blocks that are internal to larger blocks: smaller blocks 718-722 are not shown in FIG. 7C, where smaller blocks 718-722 are internal to larger block 716C; and smaller blocks 726-730 are not shown in FIG. 7C, where smaller blocks 726-730 are internal to larger block 724.

Flowchart 710C shows a different sequence of blocks than flowchart 712B. Without taking into consideration smaller blocks that are internal to larger blocks, flowchart 710C shows the following sequence: block 712→block 714→block 724→block 716.

FIG. 7D is a flowchart 710D of a method of fabricating a device, in accordance with some embodiments.

Flowchart 710D is an example of block 704 of FIG. 7A. Flowchart 710D includes blocks 742-764. In some embodiments, blocks 742-764 have a sequence of flow other than that shown in flowchart 710D. Examples provided in the context of flowchart 710D assume first, second and third orthogonal directions that are, e.g., correspondingly parallel to the X-axis, the Y-axis and the Z-axis. The method of flowchart 710D is implementable, for example, using IC manufacturing system 900 (FIG. 9, discussed below), in accordance with some embodiments. Examples of a device which can be manufactured according to the method of flowchart 710D include the devices disclosed herein, devices based on the layout diagrams disclosed herein, or the like.

Flowchart 710D assumes layers that correspondingly extend in orthogonal first (e.g., parallel to Y-axis) and second (e.g., parallel to X-axis) directions, each of the layers having a thickness relative to a third direction (e.g., parallel to Z-axis). The assumed layers include a buried via (BV) layer over a buried metallization layer, an AR layer over the BV layer, and a G&MD layer over the AR layer,

At block 742, in the G&MD layer, line structures are formed that extend in the first direction (e.g., Y-axis), the forming line structures including forming first (e.g., 532(1), or the like) and second (e.g., 532(2), or the like) line structures representing correspondingly either a gate of a transistor or an isolation dummy gate (IDG). From block 742, flow proceeds to block 744.

At block 744, an MD contact is formed (e.g., 506(3) or the like). Block 744 includes blocks 746-754. Flow inside block 744 proceeds to block 746.

At block 746, a first part (e.g., 608(31), 608(32), or the like) of the MD contact is formed in the G&MD layer. From block 746, flow proceeds to block 748.

At block 748, a second part (e.g., 608(33), or the like) of the MD contact is formed in the AR layer. From block 748, flow proceeds to block 750.

At block 750, ends of the MD contact (e.g., 506(5)) are extended correspondingly oppositely in the first direction (e.g., Y-axis). From block 750, flow proceeds to block 752.

At block 752, the first part (e.g., 608(31), 608(32), or the like) of the MD contact is located between the first (e.g., 532(1)) and second (e.g., 532(2)) line structures. From block 752, flow proceeds to block 754.

At block 754, first and second sides of the MD contact (e.g., 506(5)) correspondingly are extend oppositely in the second direction (e.g., X-axis) towards the first (e.g., 532(1)) and second (e.g., 532(2)) line structures but also being separated therefrom by corresponding first (e.g., 556(1)) and second (e.g., 556(2)) gaps. From block 754, flow exits block 744 and proceeds to block 756.

At block 756, a BV structure (e.g., 520(1)) is formed. Block 756 includes blocks 758-762. Inside block 756, flow proceeds to block 758.

At block 758, a first part (e.g., 620(1), 620(2)) of the BV structure is formed in the BV layer under the MD contact resulting in coupling therebetween. From block 758, flow proceeds to block 760.

At block 760, ends of the BV structure (e.g., 520(1)) correspondingly are extended oppositely in the first direction (e.g., Y-axis). From block 760, flow proceeds to block 762.

At block 762, first (e.g., left) and second (e.g., right) sides of the BV structure (e.g., 520(1)) correspondingly are extended oppositely in the second direction (e.g., X-axis) to be proximal to the first (e.g., 532(1)) and second (e.g., 532(2)) line structures but to be free from extending beyond the first and second line structures. From block 762, flow exits block 756 and proceeds to block 764.

At block 764, a buried segment (e.g., 528(1)) is formed in a buried metallization layer and coupled to the BV structure (e.g., 520(1)).

In some embodiments, block 764 includes: extending ends of the buried segment (e.g., 528(1)) correspondingly oppositely in the second direction (X-axis); extending a first side (e.g., right side in FIG. 6A) of the buried segment (e.g., 628(1)) to be proximal to the first side (e.g., right side in FIG. 6A) of the BV structure (e.g., 520(1)) relative to the first direction (Y-axis), and extending a second side (e.g., left side in FIG. 6A) of the buried segment in the second direction (Y-axis) to at least be aligned with the second side (e.g., right side in FIG. 6A) of the BV structure (620(1)).

In some embodiments, block 764 includes: extending the second side (e.g., left side in FIG. 6A) of the buried segment in the second direction (e.g., Y-axis) substantially beyond the second side (e.g., left side in FIG. 6A) of the BV structure (e.g., 620(1)).

In some embodiments, flowchart 710D further includes: a block 740 (not shown in FIG. 7D) before block 742 that includes forming active regions in the AR layer and extending in the first direction (e.g., X-axis). Block 740 includes a block 740(1) (not shown in FIG. 7D) and a block 740(2) (not shown in FIG. 7D). In block 740, flow proceeds to block 741(1).

At block 740(1), a first active region (e.g., 502) is formed having a first dummy portion (e.g., 503, 603) that extends between the first (e.g., 532(1)) and second (e.g., 532(2)) line structures, the first dummy portion (e.g., 503) being free from extending beyond the first (e.g., 532(1)) and second (e.g., 532(2)) line structures. From block 740(1), flow proceeds to block 741(2).

At block 741(2), a second active region (e.g., 504) is formed having a second dummy portion (e.g., 505, 605) that extends between the first (e.g., 532(1)) and second (e.g., 532(2)) line structures, the second dummy portion (e.g., 505) being free from extending beyond the first (e.g., 532(1)) and second (e.g., 532(2)) line structures. From block 741(2), flow proceeds out of block 740. In such embodiments, block 744 further includes blocks 745(1)-745(3) (not shown in FIG. 7D). Block 745(1) (not shown in FIG. 7D) includes, relative to the second direction (Y-axis), locating the second portion (e.g., 608(33)) of the MD contact (e.g., 606(5)) between the first (e.g., 603) and second (e.g., 605) dummy portions. Block 745(2) includes coupling the MD contact (e.g., 506(5)) to the BV structure (e.g., 520(1)). Block 745(3) includes extending first and second ends of the MD contact (e.g., 506(5)) correspondingly oppositely in the first direction (Y-axis) and away from the MD contact (e.g., 506(5)) to overlap the first (e.g., 503) and second (e.g., 505) dummy portions but to be free from extending beyond the first (e.g., 503) and second (e.g., 505) dummy portions. In some embodiments, block 745(3) includes extending the ends of the BV structure (e.g., 620(1)) correspondingly at least partially underneath the first (e.g., 503) and second (e.g., 505) dummy portions relative to the first direction (e.g., Y-axis).

In some embodiments, the first (e.g., 530(12)) and second (e.g., 530(13)) line structures represent gates of corresponding transistor, and block 742 further includes: forming third (e.g., 532(13)), fourth (e.g., 532(14)), fifth (e.g., 532(11)) and sixth (e.g., 532(12)) line structures representing IDGs; and locating the first (e.g., 530(12)) and second (e.g., 530(13)) line structures between the third (e.g., 532(13)) and fourth (e.g., 532(14)) line structures.

Relative to the first direction (e.g., X-axis): the third (e.g., 532(13)) and fourth (e.g., 532(14)) line structures represent first (e.g., left in FIG. 5B) and second (e.g., right in FIG. 5B) side boundaries of a first cell region (e.g., 558(12)); and the fifth (e.g., 532(11)) and sixth (e.g., 532(12)) line structures represent first (e.g., left in FIG. 5B) and second (e.g., right in FIG. 5B) side boundaries of a second cell region (558(11)). In such embodiments, block 742 further includes: relative to the first direction (e.g., X-axis), separating the third (e.g., 532(13)) and sixth (e.g., 532(12)) line structures by an inter-cell gap (e.g., by inspection of FIG. 5B). In such embodiments, flowchart 710D further includes a block 766 (not shown in FIG. 7D).

Block 766 includes forming, in a metallization layer (e.g., M2) over the G&MD layer, a metallization segment (e.g., 564). Block 766 includes blocks 768(1)-768(3) (not shown in FIG. 7D). Inside block 766, flow proceeds to block 768(1). At block 768(1), the metallization segment (e.g., 564) is coupled to the MD contact (e.g., 506(1)). From block 768(1), flow proceeds to block 768(2). At block 768(2), the metallization segment (e.g., 564) is extended from the first cell region (e.g., 558(12)) into the second cell region (e.g., 558(11)) relative to the second direction (e.g., X-axis). From block 768(2), flow proceeds to block 768(3). At block 768(3), the metallization segment (e.g., 564) also is coupled to the second cell region (e.g., 558(11)).

FIG. 8 is a block diagram of an electronic design automation (EDA) system 800 in accordance with some embodiments.

In some embodiments, EDA system 800 includes an automatic placement and routing (APR) system. In some embodiments, EDA system 800 is a general purpose computing device including a hardware processor 802 and a non-transitory, computer-readable storage medium 804. Storage medium 804, amongst other things, is encoded with, i.e., stores, computer program code 806, i.e., a set of executable instructions. Execution of instructions 806 by hardware processor 802 represents (at least in part) an EDA tool which implements a portion or all of, e.g., methods such as the methods disclosed herein of generating layout diagrams, methods of generating layout diagrams such as the layout diagrams disclosed herein or layout diagrams corresponding to the devices disclosed herein, or the like, in accordance with one or more embodiments (hereinafter, the noted processes and/or methods).

Storage medium 804, amongst other things, stores layout diagrams 811 such as the layout diagrams disclosed herein, other the like.

Processor 802 is electrically coupled to computer-readable storage medium 804 via a bus 808. Processor 802 is further electrically coupled to an I/O interface 810 by a bus 808. A network interface 812 is further electrically connected to processor 802 via bus 808. Network interface 812 is connected to a network 814, so that processor 802 and computer-readable storage medium 804 are capable of connecting to external elements via network 814. Processor 802 is configured to execute computer program code 806 encoded in computer-readable storage medium 804 in order to cause EDA system 800 to be usable for performing a portion or all of the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, computer-readable storage medium 804 is an electronic, magnetic, optical, electromagnetic, infrared, and/or a semiconductor system (or apparatus or device). For example, computer-readable storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 804 includes a compact disk-read only memory (CD-ROM), a compact disk-read/write (CD-R/W), and/or a digital video disc (DVD).

In one or more embodiments, storage medium 804 stores computer program code 806 configured to cause EDA system 800 (where such execution represents (at least in part) the EDA tool) to be usable for performing a portion or all of the noted processes and/or methods. In one or more embodiments, storage medium 804 further stores information which facilitates performing a portion or all of the noted processes and/or methods. In one or more embodiments, storage medium 804 stores library 807 of standard cells including such standard cells as disclosed herein. In some embodiments, storage medium 804 stores one or more layout diagrams 811.

EDA system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

EDA system 800 further includes network interface 812 coupled to processor 802. Network interface 812 allows EDA system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 800.

EDA system 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. EDA system 800 is configured to receive information related to a user interface (UI) through I/O interface 810. The information is stored in computer-readable medium 804 as UI 842.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 800. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 9 is a block diagram of an integrated circuit (IC) manufacturing system 900, and an IC manufacturing flow associated therewith, in accordance with some embodiments.

In some embodiments, based on the layout diagram generated by 702 of FIG. 7A, the IC manufacturing system 900 implements block 704 of FIG. 7A wherein at least one of (A) one or more semiconductor masks or (B) at least one component in a layer of an inchoate semiconductor integrated circuit is fabricated using manufacturing system 900. In some embodiments, the IC manufacturing system 900 implements the flowcharts of FIGS. 7A-7B.

In FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout 922. IC design layout 922 includes various geometrical patterns designed for an IC device 960. The geometrical patterns correspond to patterns of metal, oxide, or semiconductor layers that make up the various components of IC device 960 to be fabricated. The various layers combine to form various IC features. For example, a portion of IC design layout 922 includes various IC features, such as an active region, gate terminal, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house 920 implements a proper design procedure to form IC design layout 922. The design procedure includes one or more of logic design, physical design or place and route. IC design layout 922 is presented in one or more data files having information of the geometrical patterns. For example, IC design layout 922 is expressed in a GDSII file format or DFII file format.

Mask house 930 includes data preparation 932 and mask fabrication 934. Mask house 930 uses IC design layout 922 to manufacture one or more masks 935 to be used for fabricating the various layers of IC device 960 according to IC design layout 922. Mask house 930 performs mask data preparation 932, where IC design layout 922 is translated into a representative data file (“RDF”). Mask data preparation 932 supplies the RDF to mask fabrication 934. Mask fabrication 934 includes a mask writer. A mask writer converts the RDF to an image on a substrate, such as a mask (reticle) or a semiconductor wafer. The design layout is manipulated by mask data preparation 932 to comply with particular characteristics of the mask writer and/or requirements of IC fab 950. In FIG. 9, mask data preparation 932, mask fabrication 934, and mask 935 are illustrated as separate elements. In some embodiments, mask data preparation 932 and mask fabrication 934 are collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout 922. In some embodiments, mask data preparation 932 includes further resolution enhancement techniques (RET), such as off-axis illumination, sub-resolution adjust features, phase-shifting masks, other suitable techniques, and the like or combinations thereof. In some embodiments, inverse lithography technology (ILT) is further used, which treats OPC as an inverse imaging problem.

In some embodiments, mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 934, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout 922 to fabricate a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are be repeated to further refine IC design layout 922.

The above description of mask data preparation 932 has been simplified for the purposes of clarity. In some embodiments, mask data preparation 932 includes additional features such as a logic operation (LOP) to modify the IC design layout according to manufacturing rules. Additionally, the processes applied to IC design layout 922 during data preparation 932 may be executed in a variety of different orders.

After mask data preparation 932 and during mask fabrication 934, a mask 935 or a group of masks 935 are fabricated based on the modified IC design layout. In some embodiments, an electron-beam (c-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

IC fab 950 is an IC fabrication business that includes one or more manufacturing facilities for the fabrication of a variety of different IC products. In some embodiments, IC fab 950 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab 950 uses mask (or masks) 935 fabricated by mask house 930 to fabricate IC device 960 using fabrication tools 952. Thus, IC fab 950 at least indirectly uses IC design layout 922 to fabricate IC device 960. In some embodiments, a semiconductor wafer 953 is fabricated by IC fab 950 using mask (or masks) 935 to form IC device 960. Semiconductor wafer 953 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, a device includes: a first active region; first and second ohmic-contact layers correspondingly on, and coupled to, a front side and a back side of a first portion of the first active region; a metal-to-source/drain (MD) contact including a first part on the first ohmic-contact layer and at least a second part or a third part correspondingly aside a first lateral side or a second lateral side of the first portion of the first active region, the first part of the MD contact being coupled to the first ohmic-contact layer; and a buried-via (BV) structure including: a first part under, and coupled to, the second ohmic-contact layer; and a second part under, and coupled to, the MD contact.

In some embodiments, each of the first and second ohmic-contact layers includes a corresponding silicide layer.

In some embodiments, the device further includes third or fourth ohmic-contact layers correspondingly on, and coupled to, the first lateral side or the second lateral side of the first portion of the first active region, and wherein: the second part or the third part of the MD contact is coupled correspondingly to the third ohmic contact layer or the fourth ohmic-contact layer.

In some embodiments, the third ohmic-contact layer includes a silicide layer; or the fourth ohmic-contact layer includes a silicide layer.

In some embodiments, the device further includes: first and second dielectric layers correspondingly on the first lateral side or the second lateral side of the first portion of the first active region; and wherein the second part or the third part of the MD contact is correspondingly on the first dielectric layer or the second dielectric layer.

In some embodiments, the BV structure further includes at least a second part or a third part correspondingly aside the first lateral side or the second lateral side of the first portion of the first active region; and the second part or the third part of the MD contact is correspondingly on, and coupled to, the second part or the third part of the BV structure.

In some embodiments, the BV structure further includes the second part and the third part; the MD contact includes the second part and the third part; and the second part and the third part of the MD contact are correspondingly on, and coupled to, the second part and the third part of the BV structure.

In some embodiments, a lower surface at the back side of the first portion of the first active region is substantially planar; an upper surface of the first part of the BV structure is substantially planar and substantially parallel to the lower surface of the first portion of the first active region; an upper surface of the second part or the third part of the BV structure is substantially planar; the upper surface of the second part or the third part of the BV structure further is substantially coplanar with the upper surface of the first part of the BV structure; and the second part or the third part of the MD contact correspondingly extends down so as to be on, and coupled to, the upper surface correspondingly of the second part or the third part of the BV structure.

In some embodiments, the device further includes: upper and lower surfaces correspondingly at the front and back sides of the first portion of the first active region are substantially planar; an upper surface of the second part or the third part of the BV structure extends substantially above the lower surface of the first portion of the first active region; and the second part or the third part of the MD contact correspondingly extends substantially below the upper surface of the first portion of the first active region so as to be on, and coupled to, the upper surface of the second part or the third part of the BV structure.

In some embodiments, the device further includes: a second active region; third and fourth ohmic-contact layers correspondingly on, and coupled to, a front side and a back side of a first portion of the second active region; and wherein first lateral side and second lateral side of the first portion of the second active region are correspondingly proximal and distal to the first and second lateral sides of the first portion of the first active region; the MD contact includes the second part and the third part; the second part of the MD contact is aside the first lateral side of the first portion of the first active region; the third part of the MD contact is aside the second lateral side of the first portion of the first active region; the MD contact further includes a fourth part on the third ohmic-contact layer of the first portion of the second active region, and a fifth part correspondingly aside the second lateral side of the first portion of the second active region, the fourth part of the MD contact being coupled to the third ohmic-contact layer; and the second part of the BV structure is under, and coupled to, the second part of the MD contact; and the BV structure further includes: a third part of the BV structure under, and coupled to, the third part of the MD contact; a fourth part of the BV structure under, and coupled to, the fourth ohmic-contact layer; and a fifth part of the BV structure under, and coupled to, the fifth part of the MD contact.

In some embodiments, a lower surface at the back side of the first portion of each of the first and second active regions is substantially planar; an upper surface of each of the first and fourth parts of the BV structure is substantially planar and substantially parallel to the lower surfaces of the first portions correspondingly of the first and second active regions; an upper surface of at least one of the second, third or fifth parts of the BV structure is substantially planar; the upper surface of the second, third or fifth part of the BV structure further is substantially coplanar with the upper surface of each of the first and fourth parts of the BV structure; and the second, third or fifth parts of the MD contact correspondingly extends down so as to be on, and coupled to, the upper surface correspondingly of the second, third or fifth parts of the BV structure.

In some embodiments, a lower surface correspondingly at the back side of the first portion of each of the first and second active regions is substantially planar; and an upper surface of at least one of the second, third or fifth parts of the BV structure extends substantially above the lower surface of the first portion of each of the first and second active regions.

In some embodiments, a device includes relative to layers correspondingly extending in orthogonal first and second directions, each of the layers having a thickness relative to a third direction, the layers including a buried via (BV) layer over a buried metallization layer, an active region (AR) layer over the BV layer, and a first layer over the AR layer, line structures in the first layer that extend in the second direction, the line structures including first and second line structures representing correspondingly either a gate of a transistor or an isolation dummy gate (IDG); a metal-to-source/drain-region (MD) contact having a first part in the first layer and a second part in the AR layer, the MD contact having ends correspondingly extending oppositely in the second direction, and the first part of the MD contact being between the first and second line structures, first and second sides of the MD contact correspondingly extending oppositely in the first direction towards the first and second line structures but being separated therefrom by corresponding first and second gaps; a BV structure in at least the BV layer, the BV structure being under and coupled to second part of the MD contact, the BV structure having ends correspondingly extending oppositely in the second direction, and first and second sides of the BV structure correspondingly extending oppositely in the first direction to be proximal to the first and second line structures but being free from extending beyond the first and second line structures; and relative to the third direction, a buried segment in a buried metallization layer under the BV layer and coupled to the BV structure.

In some embodiments, the device further includes: first and second active regions in the AR layer and extending in the first direction, the first and second active regions correspondingly having first and second dummy portions extending between the first and second line structures, the first and second dummy portions being free from extending beyond the first and second line structures; and wherein relative to the second direction, a first portion of the MD contact is between the first and second dummy portions and is coupled to the BV structure; and first and second ends of the MD contact correspondingly extending oppositely in the second direction away from the first portion of the MD contact to overlap the first and second dummy portions but be free from extending beyond the first and second dummy portions.

In some embodiments, relative to the second direction, ends of the BV structure correspondingly extend at least partially underneath the first and second dummy portions.

In some embodiments, the first and second line structures represent gates of corresponding transistors; the first and second line structures are between third and fourth ones of the line structures; the third and fourth line structures represent IDGs; relative to the first direction, the third and fourth line structures represent first and second side boundaries of a first cell region; fifth and sixth ones of the line structures represent IDGs; relative to the first direction, the fifth and sixth line structures represent first and second side boundaries of a second cell region; relative to the first direction, the third and sixth line structures are separated by an inter-cell gap; and the device further includes: a metallization segment in a metallization layer (M2) over the first layer, the metallization segment being coupled to the MD contact, the metallization segment extending from the first cell region into the second cell region relative to the first direction, and the metallization segment also being coupled to the second cell region.

In some embodiments, a method (of manufacturing a device) includes: forming active regions including: forming a first active region; forming ohmic-contact layers including forming a first ohmic-contact layer on, and coupled to, a front side of a first portion of the first active region, and forming a second ohmic-contact layer on, and coupled to, a back side of the first portion of the first active region;

forming a metal-to-source/drain (MD) contact including forming a first part of the MD contact on the first ohmic-contact layer resulting in coupling therebetween, and forming a second part of the MD contact aside a first lateral side of the first portion of the first active region or forming a third part of the MD contact aside a second lateral side of the first portion of the first active region; and forming a buried-via (BV) structure including forming a first part of the BV structure under, and coupled to, the second ohmic-contact layer, and forming a second part of the BV structure under, and coupled to, the second part or the third part of the MD contact.

In some embodiments, the forming ohmic-contact layers further includes forming a third ohmic-contact layer on, and coupled to, the first lateral side of the first portion of the first active region, or forming a fourth ohmic-contact layer on, and coupled to, the second lateral side of the first portion of the first active region; and the forming a metal-to-source/drain (MD) contact further includes coupling the second part of the MD contact to the third ohmic contact layer. or coupling the third part of the MD contact to the fourth ohmic-contact layer.

In some embodiments, the forming a buried-via (BV) structure further includes forming a second part of the BV structure aside the first lateral side of the first portion of the first active region, or forming a third part of the BV structure aside the second lateral side of the first portion of the first active region; and the forming a metal-to-source/drain (MD) contact further includes coupling the second part of the MD contact to the second part of the BV structure, or coupling the third part of the MD contact to the third part of the BV structure.

In some embodiments, the forming active regions includes forming a second active region, a first lateral side and a second lateral side of the first portion of the second active region being correspondingly proximal and distal to the first and second lateral sides of the first portion of the first active region; the forming ohmic-contact layers further includes forming a third ohmic-contact layer on, and coupled to, a front side of a first portion of the second active region, and forming a fourth ohmic-contact layer on, and coupled to, a back side of the first portion of the second active region; and the forming a metal-to-source/drain (MD) contact further includes the forming a second part of the MD contact and the forming a third part of the MD contact; the second part of the MD contact is aside the first lateral side of the first portion of the first active region; the third part of the MD contact is aside the second lateral side of the first portion of the first active region; the second part of the BV structure is under, and coupled to, the second part of the MD contact; the forming a metal-to-source/drain (MD) contact further includes forming a fourth part of the MD contact on the third ohmic-contact layer of the first portion of the second active region resulting in coupling therebetween, and forming a fifth part of the MD contact aside the second lateral side of the first portion of the second active region; and the forming a buried-via (BV) structure further includes forming a third part of the BV structure under, and coupled to, the third part of the MD contact, forming a fourth part of the BV structure under, and coupled to, the fourth ohmic-contact layer, and forming a fifth part of the BV structure under, and coupled to, the fifth part of the MD contact.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

1. A device comprising:
a first active region;
first and second ohmic-contact layers correspondingly on, and coupled to, a front side and a back side of a first portion of the first active region;
a metal-to-source/drain (MD) contact including a first part on the first ohmic-contact layer and at least a second part or a third part correspondingly aside a first lateral side or a second lateral side of the first portion of the first active region, the first part of the MD contact being coupled to the first ohmic-contact layer; and
a buried-via (BV) structure including:
a first part under, and coupled to, the second ohmic-contact layer; and
a second part under, and coupled to, the MD contact.

2. The device of claim 1, wherein:
each of the first and second ohmic-contact layers includes a corresponding silicide layer.

3. The device of claim 1, further comprising:
third or fourth ohmic-contact layers correspondingly on, and coupled to, the first lateral side or the second lateral side of the first portion of the first active region; and
wherein:
the second part or the third part of the MD contact is coupled correspondingly to the third ohmic contact layer or the fourth ohmic-contact layer.

4. The device of claim 3, wherein:
the third ohmic-contact layer includes a silicide layer; or
the fourth ohmic-contact layer includes a silicide layer.

5. The device of claim 1, further comprising:
first and second dielectric layers correspondingly on the first lateral side or the second lateral side of the first portion of the first active region; and
wherein:
the second part or the third part of the MD contact is correspondingly on the first dielectric layer or the second dielectric layer.

6. The device of claim 1, wherein:
the BV structure further includes at least a second part or a third part correspondingly aside the first lateral side or the second lateral side of the first portion of the first active region; and
the second part or the third part of the MD contact is correspondingly on, and coupled to, the second part or the third part of the BV structure.

7. The device of claim 6, wherein:
the BV structure further includes the second part and the third part;
the MD contact includes the second part and the third part; and
the second part and the third part of the MD contact are correspondingly on, and coupled to, the second part and the third part of the BV structure.

8. The device of claim 6, wherein:
a lower surface at the back side of the first portion of the first active region is substantially planar;
an upper surface of the first part of the BV structure is substantially planar and substantially parallel to the lower surface of the first portion of the first active region;
an upper surface of the second part or the third part of the BV structure is substantially planar;
the upper surface of the second part or the third part of the BV structure further is substantially coplanar with the upper surface of the first part of the BV structure; and
the second part or the third part of the MD contact correspondingly extends down so as to be on, and coupled to, the upper surface correspondingly of the second part or the third part of the BV structure.

9. The device of claim 6, wherein:
upper and lower surfaces correspondingly at the front and back sides of the first portion of the first active region are substantially planar;
an upper surface of the second part or the third part of the BV structure extends substantially above the lower surface of the first portion of the first active region; and
the second part or the third part of the MD contact correspondingly extends substantially below the upper surface of the first portion of the first active region so as to be on, and coupled to, the upper surface of the second part or the third part of the BV structure.

10. The device of claim 1, further comprising:
a second active region;
third and fourth ohmic-contact layers correspondingly on, and coupled to, a front side and a back side of a first portion of the second active region; and
wherein:
first lateral side and second lateral side of the first portion of the second active region are correspondingly proximal and distal to the first and second lateral sides of the first portion of the first active region;
the MD contact includes the second part and the third part;
the second part of the MD contact is aside the first lateral side of the first portion of the first active region;
the third part of the MD contact is aside the second lateral side of the first portion of the first active region;
the MD contact further includes a fourth part on the third ohmic-contact layer of the first portion of the second active region, and a fifth part correspondingly aside the second lateral side of the first portion of the second active region, the fourth part of the MD contact being coupled to the third ohmic-contact layer; and
the second part of the BV structure is under, and coupled to, the second part of the MD contact; and
the BV structure further includes:
a third part of the BV structure under, and coupled to, the third part of the MD contact;
a fourth part of the BV structure under, and coupled to, the fourth ohmic-contact layer; and
a fifth part of the BV structure under, and coupled to, the fifth part of the MD contact.

11. The device of claim 10, wherein:
a lower surface at the back side of the first portion of each of the first and second active regions is substantially planar;
an upper surface of each of the first and fourth parts of the BV structure is substantially planar and substantially parallel to the lower surfaces of the first portions correspondingly of the first and second active regions;
an upper surface of at least one of the second, third or fifth parts of the BV structure is substantially planar;
the upper surface of the second, third or fifth part of the BV structure further is substantially coplanar with the upper surface of each of the first and fourth parts of the BV structure; and
the second, third or fifth parts of the MD contact correspondingly extends down so as to be on, and coupled to, the upper surface correspondingly of the second, third or fifth parts of the BV structure.

12. The device of claim 10, wherein:
a lower surface correspondingly at the back side of the first portion of each of the first and second active regions is substantially planar; and
an upper surface of at least one of the second, third or fifth parts of the BV structure extends substantially above the lower surface of the first portion of each of the first and second active regions.

13. A device comprising:
relative to layers correspondingly extending in orthogonal first and second directions, each of the layers having a thickness relative to a third direction, the layers including a buried via (BV) layer over a buried metallization layer, an active region (AR) layer over the BV layer, and a first layer over the AR layer,
line structures in the first layer that extend in the second direction, the line structures including first and second line structures representing correspondingly either a gate of a transistor or an isolation dummy gate (IDG);
a metal-to-source/drain-region (MD) contact having a first part in the first layer and a second part in the AR layer,
the MD contact having ends correspondingly extending oppositely in the second direction, and
the first part of the MD contact being between the first and second line structures,
first and second sides of the MD contact correspondingly extending oppositely in the first direction towards the first and second line structures but being separated therefrom by corresponding first and second gaps;
a BV structure in at least the BV layer, the BV structure being under and coupled to second part of the MD contact,
the BV structure having ends correspondingly extending oppositely in the second direction, and
first and second sides of the BV structure correspondingly extending oppositely in the first direction to be proximal to the first and second line structures but being free from extending beyond the first and second line structures; and
relative to the third direction, a buried segment in a buried metallization layer under the BV layer and coupled to the BV structure.

14. The device of claim 13, further comprising:
first and second active regions in the AR layer and extending in the first direction, the first and second active regions correspondingly having first and second dummy portions extending between the first and second line structures, the first and second dummy portions being free from extending beyond the first and second line structures; and
wherein:
relative to the second direction, a first portion of the MD contact is between the first and second dummy portions and is coupled to the BV structure; and
first and second ends of the MD contact correspondingly extending oppositely in the second direction away from the first portion of the MD contact to overlap the first and second dummy portions but be free from extending beyond the first and second dummy portions.

15. The device of claim 14, wherein:
relative to the second direction, ends of the BV structure correspondingly extend at least partially underneath the first and second dummy portions.

16. The device of claim 13, wherein:
the first and second line structures represent gates of corresponding transistors;
the first and second line structures are between third and fourth ones of the line structures;
the third and fourth line structures represent IDGs;
relative to the first direction, the third and fourth line structures represent first and second side boundaries of a first cell region;
fifth and sixth ones of the line structures represent IDGs;
relative to the first direction, the fifth and sixth line structures represent first and second side boundaries of a second cell region;
relative to the first direction, the third and sixth line structures are separated by an inter-cell gap; and
the device further comprises:
a metallization segment in a metallization layer (M2) over the first layer,
the metallization segment being coupled to the MD contact;
the metallization segment extending from the first cell region into the second cell region relative to the first direction, and
the metallization segment also being coupled to the second cell region.

17. A method of manufacturing a device, the method comprising:
forming active regions including:
forming a first active region;
forming ohmic-contact layers including:
forming a first ohmic-contact layer on, and coupled to, a front side of a first portion of the first active region; and
forming a second ohmic-contact layer on, and coupled to, a back side of the first portion of the first active region;
forming a metal-to-source/drain (MD) contact including:
forming a first part of the MD contact on the first ohmic-contact layer resulting in coupling therebetween; and
forming a second part of the MD contact aside a first lateral side of the first portion of the first active region; or
forming a third part of the MD contact aside a second lateral side of the first portion of the first active region; and
forming a buried-via (BV) structure including:
forming a first part of the BV structure under, and coupled to, the second ohmic-contact layer; and
forming a second part of the BV structure under, and coupled to, the second part or the third part of the MD contact.

18. The method of claim 17, wherein:
the forming ohmic-contact layers further includes:
forming a third ohmic-contact layer on, and coupled to, the first lateral side of the first portion of the first active region; or
forming a fourth ohmic-contact layer on, and coupled to, the second lateral side of the first portion of the first active region; and
the forming a metal-to-source/drain (MD) contact further includes:
coupling the second part of the MD contact to the third ohmic contact layer; or
coupling the third part of the MD contact to the fourth ohmic-contact layer.

19. The method of claim 17, wherein:
the forming a buried-via (BV) structure further includes:
forming a second part of the BV structure aside the first lateral side of the first portion of the first active region; or
forming a third part of the BV structure aside the second lateral side of the first portion of the first active region; and
the forming a metal-to-source/drain (MD) contact further includes:
coupling the second part of the MD contact to the second part of the BV structure; or
coupling the third part of the MD contact to the third part of the BV structure.

20. The method of claim 17, wherein:
the forming active regions includes:
forming a second active region,
a first lateral side and a second lateral side of the first portion of the second active region being correspondingly proximal and distal to the first and second lateral sides of the first portion of the first active region;
the forming ohmic-contact layers further includes:
forming a third ohmic-contact layer on, and coupled to, a front side of a first portion of the second active region; and
forming a fourth ohmic-contact layer on, and coupled to, a back side of the first portion of the second active region; and
the forming a metal-to-source/drain (MD) contact further includes:
the forming a second part of the MD contact and the forming a third part of the MD contact;
the second part of the MD contact is aside the first lateral side of the first portion of the first active region;
the third part of the MD contact is aside the second lateral side of the first portion of the first active region;
the second part of the BV structure is under, and coupled to, the second part of the MD contact;
the forming a metal-to-source/drain (MD) contact further includes:
forming a fourth part of the MD contact on the third ohmic-contact layer of the first portion of the second active region resulting in coupling therebetween; and
forming a fifth part of the MD contact aside the second lateral side of the first portion of the second active region; and
the forming a buried-via (BV) structure further includes:
forming a third part of the BV structure under, and coupled to, the third part of the MD contact;
forming a fourth part of the BV structure under, and coupled to, the fourth ohmic-contact layer; and
forming a fifth part of the BV structure under, and coupled to, the fifth part of the MD contact.
